(19) United States
(12) Patent Application Publication
(10) Pub. No.: US 2026/0074715 A1
(43) Pub. Date: Mar. 12, 2026

(54) METHODS, SYSTEMS, AND APPARATUS FOR RATELESS POLAR CODING AND INCREMENTAL REDUNDANCY

(71) Applicant: Huawei Technologies Co., Ltd., Shenzhen (CN)

(72) Inventors: Huazi Zhang, Hangzhou (CN); Jiajie Tong, Hangzhou (CN); Xianbin Wang, Hangzhou (CN); Kangjian Qin, Hangzhou (CN); Jun Wang, Hangzhou (CN); Yiqun Ge, Ottawa (CA); Xiaoyan Bi, Shanghai (CN); Jianglei Ma, Ottawa (CA); Peiying Zhu, Ottawa (CA); Wen Tong, Ottawa (CA)

(21) Appl. No.: 19/336,153

(22) Filed: Sep. 22, 2025

Related U.S. Application Data
(63) Continuation of application No. PCT/CN2023/111101, filed on Aug. 3, 2023.
(60) Provisional application No. 63/454,069, filed on Mar. 23, 2023.

(51) Int. Cl. H03M 13/19

(52) U.S. Cl. CPC H03M 13/19

(57) ABSTRACT

Reduced numbers of encoded bits obtained by encoding input bits by a polar code are incrementally output, for transmission for example. The polar code comprises bit indices for placing bit values before encoding. The bit indices include a first set of bit indices for placing values of the input bits and a second set of bit indices for placing a predetermined bit value. A first reduced number of the encoded bits start from a first starting position, and a second reduced number of the encoded bits start from a second starting position different from the first starting position. The second reduced number of the encoded bits include one or more of the encoded bits not included in the first reduced number of the encoded bits. The reduced numbers of encoded bits may be output from continuous positions, in a circular buffer for example, or may include repeated bits.

### CROSS-REFERENCE TO RELATED APPLICATIONS

The present application is a continuation of International Application No. PCT/CN2023/111101, entitled “METHODS, SYSTEMS, AND APPARATUS FOR RATELESS POLAR CODING AND INCREMENTAL REDUNDANCY” and filed on Aug. 3, 2023, and claims the benefit of: U.S. provisional patent application Ser. No. 63/454,069, entitled “Methods, Systems, and Apparatus for Rateless Polar Coding and Incremental Redundancy”, filed on Mar. 23, 2023, the disclosure of which is hereby incorporated by reference in its entirety.

The present application is related to the following Patent Cooperation Treaty (PCT) applications by the same applicant:
PCT Application No. PCT/CN2023/097662, entitled “Methods, Systems, and Apparatus for Protograph-based Low Density Parity Check Coding”, filed on May 31, 2023;
PCT Application No. PCT/CN2023/092465, entitled “Methods, Systems, and Apparatus for Partial Code Rate Reduction in Polar Coding”, filed on May 6, 2023;
PCT Application No. PCT/CN2023/102653, entitled “Methods, Systems, and Apparatus for Rateless Polar Coding”, filed on Jun. 27, 2023; and
PCT Application No. PCT/CN2023/103893, entitled “Methods, Systems, and Apparatus for Rateless Polar Coding and Low-complexity Decoding”, filed on Jun. 29, 2023,
   and is also related to U.S. provisional patent application Ser. No. 63/454,070, entitled “Methods, Systems, and Apparatus for Channel-dependent Error Correction Coding”, filed on Mar. 23, 2023; U.S. provisional patent application Ser. No. 63/454,066, entitled “Methods, Systems, and Apparatus for Partial Code Rate Reduction in Polar Coding”, filed on Mar. 23, 2023; U.S. provisional patent application Ser. No. 63/454,067, entitled “Methods, Systems, and Apparatus for Rateless Polar Coding”, filed on Mar. 23, 2023; U.S. provisional patent application Ser. No. 63/454,068, entitled “Methods, Systems, and Apparatus for Rateless Polar Coding and Low-complexity Decoding”, filed on Mar. 23, 2023; PCT Application No. PCT/CN2023/083350, entitled “Methods, Systems, and Apparatus for Non-Sequential Decoding of Polar Codes”, filed on Mar. 23, 2023; PCT Application No. PCT/CN2023/083348, entitled “Methods, Systems, and Apparatus for Bit Value Placement in Polar Coding”, filed on Mar. 23, 2023; and PCT Application No. PCT/CN2023/083345, entitled “Methods, Systems, and Apparatus for Encoded Bit Reduction in Polar Coding”, filed on Mar. 23, 2023.

The disclosures of the aforementioned applications are hereby incorporated by reference in their entireties.

### TECHNICAL FIELD

The present application relates to coding, and in particular, to rateless polar coding and incremental redundancy.

### BACKGROUND

In wireless communications, channel conditions are constantly changing at both fast and slow scale due to, for example, fading effects. Accordingly, channel coding has conventionally always been designed to adapt to channel conditions. Modulation coding scheme (MCS) adaptation, in which the modulation order and code length and code rate can be changed in real time, is a powerful approach to combat varying channel conditions.

Adapting to channel conditions requires channel coding that can flexibly change code length and code rate in a fine-grained way, and at the same time achieve good error correction performance in all possible configurations. This fine-grained flexibility of channel codes remains a challenge.

Probabilistic codes such as low density parity check (LDPC) codes, which are more like random codes, may be naturally suited for flexibility. However, algebraic codes such as Reed-Muller (RM) codes and Bose-Chaudhuri-Hocquenghem (BCH) codes, are not as flexible as probabilistic codes. This is because their inherent coding structures may be compromised when code length or rate changes. Polar codes exhibit features from both probabilistic codes and algebraic codes. As a result, polar codes have a level of flexibility that lies between probabilistic codes and algebraic codes.

Rate matching, including techniques such as puncturing and shortening, are available to design rate-compatible polar codes, such as the polar codes for fifth generation (5G) new radio (NR). However, the degree of flexibility is not enough to support more advanced features such as fine-grained incremental-redundancy hybrid automatic repeat request (IR-HARQ), for example.

Ratelessness can be important for rate compatibility, and refers to a coding approach in which an encoder does not need to determine a code rate before transmission of encoded data. Current polar code constructions need to know code length, which in turn impacts code rate, before transmission. Such code constructions therefore do not quality as “rateless”. In existing polar coding schemes, code length is required during code construction, because it significantly affects the reliability of polarized subchannels and corresponding information subchannel selection.

A more flexible channel coding approach is needed.

### SUMMARY

The present disclosure encompasses embodiments related to what is referred to herein as rateless polar IR-HARQ. Some embodiments support or provide ratelessness through encoding to a maximum code length, and any of several approaches may be applied transmitting or otherwise outputting code bits to support or provide incremental redundancy.

According to an aspect of the present disclosure, a method involves encoding input bits by a polar code to obtain a number of encoded bits. The polar code comprises a number of bit indices for placing bit values before encoding, and the bit indices include a first set of bit indices for placing values of the input bits and a second set of bit indices for placing a predetermined bit value. Such a method may also involve outputting a first reduced number of the encoded bits starting from a first starting position, and outputting a second reduced number of the encoded bits. The second reduced number of the encoded bits include one or more of the encoded bits not included in the first reduced number of the encoded bits, and start from a second starting position that is different from the first starting position.

Another method involves receiving a first reduced number and a second reduced number of encoded bits encoded by a polar code, and decoding the first reduced number of encoded bits and the second reduced number of encoded bits to obtain decoded input bits. The second reduced number of the encoded bits include one or more of the encoded bits not included in the first reduced number of the encoded bits and start from a second starting position different from a first starting position of the first reduced number of the encoded bits. The polar code comprises a number of bit indices for placing bit values before encoding, and the bit indices include a first set of bit indices for placing values of input bits and a second set of bit indices for placing a predetermined bit value.

An apparatus according to an embodiment includes an encoder and an interface. The encoder is for encoding input bits by a polar code to obtain a number of encoded bits. The polar code comprises a number of bit indices for placing bit values before encoding, and the bit indices include a first set of bit indices for placing values of the input bits and a second set of bit indices for placing a predetermined bit value. The interface is coupled to the encoder, for outputting a first reduced number of the encoded bits starting from a first starting position, and outputting a second reduced number of the encoded bits. The second reduced number of the encoded bits include one or more of the encoded bits not included in the first reduced number of the encoded bits, and start from a second starting position different from the first starting position.

According to another embodiment, an apparatus includes an interface and a decoder coupled to the interface. The interface is for receiving a first reduced number and a second reduced number of encoded bits encoded by a polar code, and the decoder is for decoding the first reduced number of encoded bits and the second reduced number of encoded bits to obtain decoded input bits. As in other embodiments, the polar code comprises a number of bit indices for placing bit values before encoding, the bit indices include a first set of bit indices for placing values of the input bits and a second set of bit indices for placing a predetermined bit value, and the second reduced number of the encoded bits include one or more of the encoded bits not included in the first reduced number of the encoded bits and start from a second starting position different from a first starting position of the first reduced number of the encoded bits.

In other apparatus embodiments, an apparatus may include a processor configured to cause the apparatus to perform any of the methods as disclosed herein.

An apparatus may include a processor and a non-transitory computer readable storage medium that is coupled to the processor and stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

A system is also disclosed, and may include a first communication device and a second communication device. The first communication device is configured to transmit a first reduced number of encoded bits starting from a first starting position and a second reduced number of the encoded bits starting from a second starting position different from the first starting position. The encoded bits are obtained by encoding input bits by a polar code that comprises a number of bit indices for placing bit values before encoding, and the bit indices include a first set of bit indices for placing values of the input bits and a second set of bit indices for placing a predetermined bit value. The second reduced number of the encoded bits include one or more of the encoded bits not included in the first reduced number of the encoded bits. The second communication device is configured to receive the first reduced number and the second reduced number of the encoded bits, and to decode the first reduced number of encoded bits and the second reduced number of encoded bits to obtain decoded input bits.

The present disclosure encompasses these and other aspects or embodiments.

### BRIEF DESCRIPTION OF THE DRAWINGS

For a more complete understanding of the present embodiments, and the advantages thereof, reference is now made, by way of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 is a trellis graph illustrating an example of a polar code.

FIG. 6 is a diagram illustrating puncturing and shortening with a cyclic buffer.

FIG. 7 is a diagram illustrating starting and ending points for output from a circular buffer.

FIG. 8 is a diagram illustrating output of bits from a circular buffer according to another embodiment.

FIG. 9 is a diagram illustrating output of bits from a circular buffer according to a further embodiment.

FIG. 10 is a diagram illustrating an embodiment that includes optional partial interleaving and puncturing.

FIG. 11 is a diagram illustrating another embodiment that includes optional partial interleaving and puncturing.

FIG. 12 is a diagram illustrating a further embodiment that includes optional partial interleaving and puncturing.

FIG. 13 is a flow diagram illustrating general example methods according to embodiments.

FIG. 14 is a block diagram illustrating an apparatus according to an embodiment.

FIG. 15 includes plots illustrating error correction performance.

### DETAILED DESCRIPTION

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

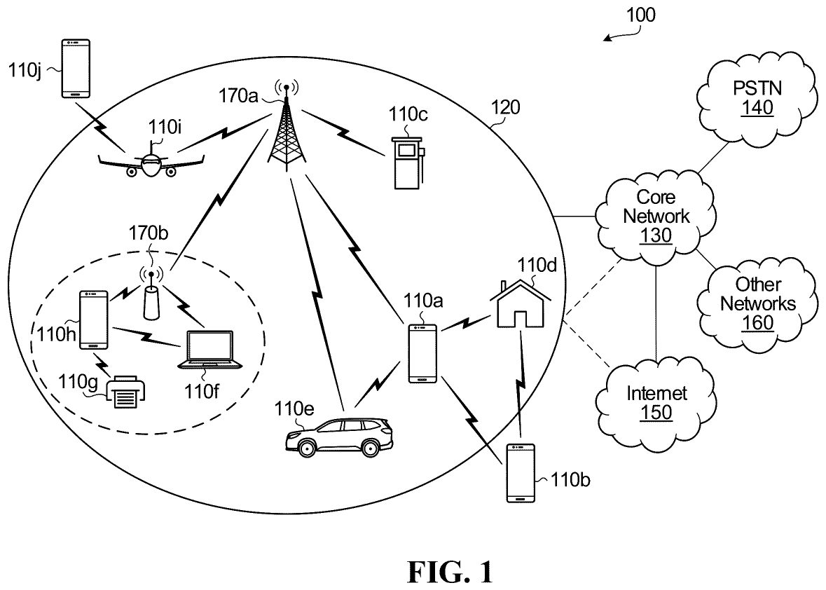

Referring to FIG. 1, as an illustrative example without limitation, a simplified schematic illustration of a communication system is provided. The communication system 100 comprises a radio access network 120. The radio access network 120 may be a next generation (e.g., sixth generation, “6G,” or later) radio access network, or a legacy (e.g., 5G, 4G, 3G or 2G) radio access network. One or more communication electric device (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

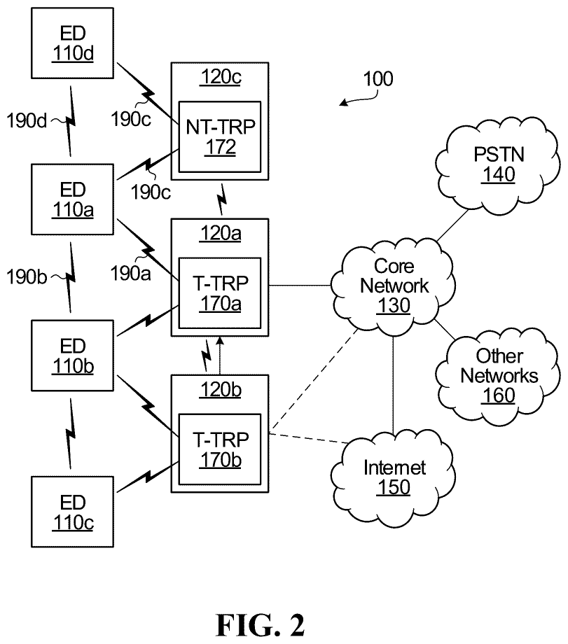

FIG. 2 illustrates an example communication system 100. In general, the communication system 100 enables multiple wireless or wired elements to communicate data and other content. The purpose of the communication system 100 may be to provide content, such as voice, data, video, signaling, and/or text, via broadcast, multicast and unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150 and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a, 170b and NT-TRP 172, the Internet 150, the core network 130, the PSTN 140, the other networks 160, or any combination of the preceding. In some examples, the ED 110a may communicate an uplink and/or downlink transmission over a terrestrial air interface 190a with T-TRP 170a. In some examples, the EDs 110a, 110b, 110c and 110d may also communicate directly with one another via one or more sidelink air interfaces 190b. In some examples, the ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), Direct Fourier Transform spread OFDMA (DFT-OFDMA) or single-carrier FDMA (SC-FDMA) in the air interfaces 190a and 190b. The air interfaces 190a and 190b may utilize other higher dimension signal spaces, which may involve a combination of orthogonal and/or non-orthogonal dimensions.

The non-terrestrial air interface 1900 can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a, 110b, 110c with various services such as voice, data and other services. The RANs 120a and 120b and/or the core network 130 may be in direct or indirect communication with one or more other RANs (not shown), which may or may not be directly served by core network 130 and may, or may not, employ the same radio access technology as RAN 120a, RAN 120b or both. The core network 130 may also serve as a gateway access between (i) the RANs 120a and 120b or the EDs 110a, 110b, 110c or both, and (ii) other networks (such as the PSTN 140, the Internet 150, and the other networks 160). In addition, some or all of the EDs 110a, 110b, 110c may include functionality for communicating with different wireless networks over different wireless links using different wireless technologies and/or protocols. Instead of wireless communication (or in addition thereto), the EDs 110a, 110b, 110c may communicate via wired communication channels to a service provider or switch (not shown) and to the Internet 150. The PSTN 140 may include circuit switched telephone networks for providing plain old telephone service (POTS). The Internet 150 may include a network of computers and subnets (intranets) or both and incorporate protocols, such as Internet Protocol (IP), Transmission Control Protocol (TCP), User Datagram Protocol (UDP). The EDs 110a, 110b, 110c may be multimode devices capable of operation according to multiple radio access technologies and may incorporate multiple transceivers necessary to support such.

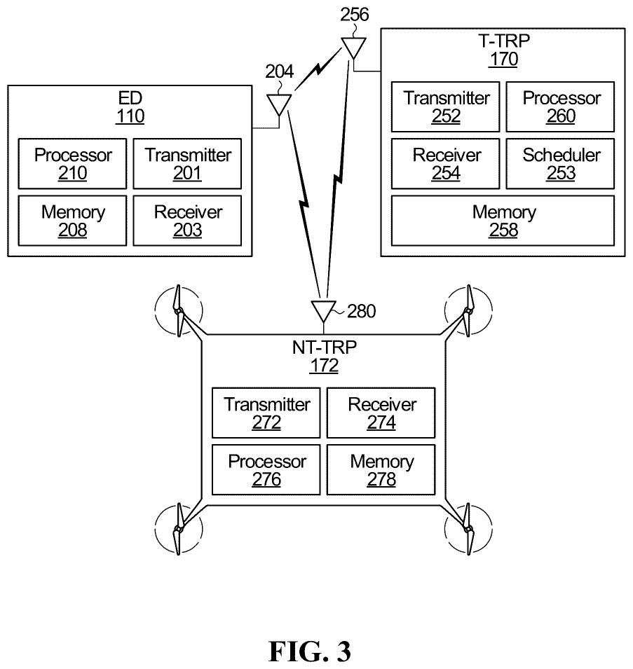

FIG. 3 illustrates another example of an ED 110 and a base station 170a, 170b and/or 170c. The ED 110 is used to connect persons, objects, machines, etc. The ED 110 may be widely used in various scenarios, for example, cellular communications, device-to-device (D2D), vehicle to everything (V2X), peer-to-peer (P2P), machine-to-machine (M2M), machine-type communications (MTC), Internet of things (IOT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices such as a watch, head mounted equipment, a pair of glasses, an industrial device, or apparatus (e.g., communication module, modem, or chip) in the forgoing devices, among other possibilities. Future generation EDs 110 may be referred to using other terms. Each base station 170a and 170b is a T-TRP and will, hereafter, be referred to as T-TRP 170. Also shown in FIG. 3, a NT-TRP will hereafter be referred to as NT-TRP 172. Each ED 110 connected to the T-TRP 170 and/or the NT-TRP 172 can be dynamically or semi-statically turned-on (i.e., established, activated or enabled), turned-off (i.e., released, deactivated or disabled) and/or configured in response to one of more of: connection availability; and connection necessity.

The ED 110 includes a transmitter 201 and a receiver 203 coupled to one or more antennas 204. Only one antenna 204 is illustrated. One, some, or all of the antennas 204 may, alternatively, be panels. The transmitter 201 and the receiver 203 may be integrated, e.g., as a transceiver. The transceiver is configured to modulate data or other content for transmission by the at least one antenna 204 or by a network interface controller (NIC). The transceiver may also be configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache and the like.

The ED 110 may further include one or more input/output devices (not shown) or interfaces (such as a wired interface to the Internet 150 in FIG. 1). The input/output devices permit interaction with a user or other devices in the network. Each input/output device includes any suitable structure for providing information to, or receiving information from, a user, such as through operation as a speaker, a microphone, a keypad, a keyboard, a display or a touch screen, including network interface communications.

The ED 110 includes the processor 210 for performing operations including those operations related to preparing a transmission for uplink transmission to the NT-TRP 172 and/or the T-TRP 170, those operations related to processing downlink transmissions received from the NT-TRP 172 and/or the T-TRP 170, and those operations related to processing sidelink transmission to and from another ED 110. Processing operations related to preparing a transmission for uplink transmission may include operations such as encoding, modulating, transmit beamforming and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g., by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g., beam angle information (BAI), received from the T-TRP 170. In some embodiments, the processor 210 may perform operations relating to network access (e.g., initial access) and/or downlink synchronization, such as operations relating to detecting a synchronization sequence, decoding and obtaining the system information, etc. In some embodiments, the processor 210 may perform channel estimation, e.g., using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201 and the processing components of the receiver 203 may each be implemented by the same or different one or more processors that are configured to execute instructions stored in a memory (e.g., in the memory 208). Alternatively, some or all of the processor 210, the processing components of the transmitter 201 and the processing components of the receiver 203 may each be implemented using dedicated circuitry, such as a programmed field-programmable gate array (FPGA), a graphical processing unit (GPU), a Central Processing Unit (CPU) or an application-specific integrated circuit (ASIC).

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g., a communication module, a modem or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g., through the use of coordinated multipoint transmissions.

The T-TRP 170 includes at least one transmitter 252 and at least one receiver 254 coupled to one or more antennas 256. Only one antenna 256 is illustrated. One, some, or all of the antennas 256 may, alternatively, be panels. The transmitter 252 and the receiver 254 may be integrated as a transceiver. The T-TRP 170 further includes a processor 260 for performing operations including those related to: preparing a transmission for downlink transmission to the ED 110; processing an uplink transmission received from the ED 110; preparing a transmission for backhaul transmission to the NT-TRP 172; and processing a transmission received over backhaul from the NT-TRP 172. Processing operations related to preparing a transmission for downlink or backhaul transmission may include operations such as encoding, modulating, precoding (e.g., multiple input multiple output (MIMO) precoding), transmit beamforming and generating symbols for transmission. Processing operations related to processing received transmissions in the uplink or over backhaul may include operations such as receive beamforming, demodulating received symbols and decoding received symbols. The processor 260 may also perform operations relating to network access (e.g., initial access) and/or downlink synchronization, such as generating the content of synchronization signal blocks (SSBs), generating the system information, etc. In some embodiments, the processor 260 also generates an indication of beam direction, e.g., BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g., to configure one or more parameters of the ED 110 and/or one or more parameters of the NT-TRP 172. Any signaling generated by the processor 260 is sent by the transmitter 252. Note that “signaling,” as used herein, may alternatively be called control signaling. Dynamic signaling may be transmitted in a control channel, e.g., a physical downlink control channel (PDCCH) and static, or semi-static, higher layer signaling may be included in a packet transmitted in a data channel, e.g., in a physical downlink shared channel (PDSCH).

The scheduler 253 may be coupled to the processor 260. The scheduler 253 may be included within, or operated separately from, the T-TRP 170. The scheduler 253 may schedule uplink, downlink and/or backhaul transmissions, including issuing scheduling grants and/or configuring scheduling-free (“configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252 and the processing components of the receiver 254 may each be implemented by the same, or different one of, one or more processors that are configured to execute instructions stored in a memory, e.g., in the memory 258. Alternatively, some or all of the processor 260, the scheduler 253, the processing components of the transmitter 252 and the processing components of the receiver 254 may be implemented using dedicated circuitry, such as a FPGA, a GPU or an ASIC.

Notably, the NT-TRP 172 is illustrated as a drone only as an example, the NT-TRP 172 may be implemented in any suitable non-terrestrial form, such as high altitude platforms, satellite, high altitude platform as international mobile telecommunication base stations and unmanned aerial vehicles, which forms will be discussed hereinafter. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110; processing an uplink transmission received from the ED 110; preparing a transmission for backhaul transmission to T-TRP 170; and processing a transmission received over backhaul from the T-TRP 170. Processing operations related to preparing a transmission for downlink or backhaul transmission may include operations such as encoding, modulating, precoding (e.g., MIMO precoding), transmit beamforming and generating symbols for transmission. Processing operations related to processing received transmissions in the uplink or over backhaul may include operations such as receive beamforming, demodulating received signals and decoding received symbols. In some embodiments, the processor 276 implements the transmit beamforming and/or receive beamforming based on beam direction information (e.g., BAI) received from the T-TRP 170. In some embodiments, the processor 276 may generate signaling, e.g., to configure one or more parameters of the ED 110. In some embodiments, the NT-TRP 172 implements physical layer processing but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272 and the processing components of the receiver 274 may each be implemented by the same or different one or more processors that are configured to execute instructions stored in a memory, e.g., in the memory 278. Alternatively, some or all of the processor 276, the processing components of the transmitter 272 and the processing components of the receiver 274 may be implemented using dedicated circuitry, such as a programmed FPGA, a GPU, a CPU or an ASIC. In some embodiments, the NT-TRP 172 may actually be a plurality of NT-TRPs that are operating together to serve the ED 110, e.g., through coordinated multipoint transmissions.

The T-TRP 170, the NT-TRP 172, and/or the ED 110 may include other components, but these have been omitted for the sake of clarity.

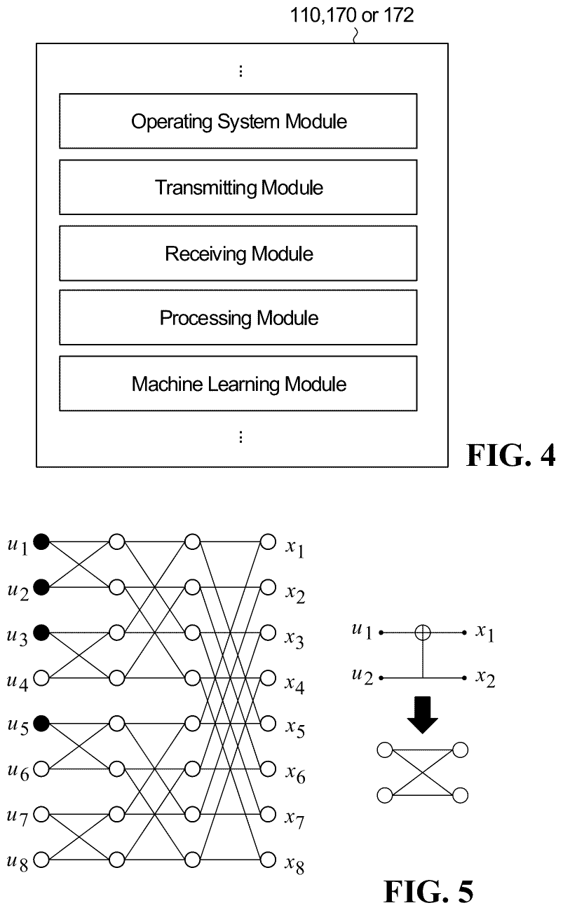

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted by a transmitting unit or by a transmitting module. A signal may be received by a receiving unit or by a receiving module. A signal may be processed by a processing unit or by a processing module. Other steps may be performed by an artificial intelligence (AI) or machine learning (ML) module. The respective units or modules may be implemented using hardware, one or more components or devices that execute software, or a combination thereof. For instance, one or more of the units or modules may be an integrated circuit, such as a programmed FPGA, a GPU, a CPU or an ASIC. It will be appreciated that where the modules are implemented using software for execution by a processor, for example, the modules may be retrieved by a processor, in whole or part as needed, individually or together for processing, in single or multiple instances, and that the modules themselves may include instructions for further deployment and instantiation.

Additional details regarding the EDs 110, the T-TRP 170 and the NT-TRP 172 are known to those of skill in the art. As such, these details are omitted here.

Having considered communications more generally above, attention will now turn to particular example embodiments.

Polar codes are linear block codes. For a polar code of length N, its generator matrix is G_{N}, and its encoding process is

$${x}_{1}^{N} = {u}_{1}^{N} {G}_{N} ,$$

where

$${u}_{1}^{N} = [ {u}_{1} , {u}_{2} , … , {u}_{N} ]$$

is a binary information vector, and

$${x}_{1}^{N} = [ {x}_{1} , {x}_{2} , … , {x}_{N} ]$$

is the binary code vector. The N×N binary generator matrix

$${G}_{N} = {F}_{2}^{⊗ n} ,$$

where

$${F}_{2} = [ \begin{matrix}1 & 0 \\ 1 & 1\end{matrix} ]$$

is the polarization kernel matrix, ⊗ is Kronecker product, and n=log₂ N.

With K information bits to be encoded into N code bits and K<N, a code rate of R=K/N<1 is obtained. This implies only part of u₁^{N} is used to carry information bits, and the remining bits of u₁^{N} are known as frozen bits. The information bit set (or information set) may be denoted by I, and the frozen bit set (or frozen set) may be denoted by F. Sometimes, there is an additional PC bit set, denoted by P. The frozen bits are known and usually set to all zeros before decoding, so they do not carry any information. The PC bits are parity-check bits of a subset of information bits, and therefore are known once the associated information bits are decoded. Decoding of polar codes attempts to recover all information bits.

Code length M may, but might not always, be a power of 2, in which case M<N. In practice, puncturing and shortening are used to reduce the number of transmitted code bits from N to M. For convenience, N is referred to as mother code length, and M is referred to as code length herein. In particular, punctured bits are untransmitted bits that are unknown to a decoder, but shortened bits are untransmitted bits that are known to the decoder (usually all zeros).

FIG. 5 is a trellis graph illustrating an example of a polar code with N=8 and K=4. Each “butterfly” in the graph is a polarization, and one butterfly is shown by way of example at the right in FIG. 5, for

$$x {}_{1}^{2} = u {}_{1}^{2} [ \begin{matrix}1 & 0 \\ 1 & 1\end{matrix} ] .$$

In the example shown, the unshaded circles at the left represent the information set I={u₄, u₆, u₇, u₈}, and the shaded circles represent the frozen set F={u₁, u₂, u₃, u₅}.

The input vector u at the left in FIG. 5 and the code vector x at the right in FIG. 5 each include a number of bit positions. The bit positions in the input vector are indexed by respective bit indices, and bit values are placed on or at those bit indices or bit positions for encoding. These bit indices or bit positions are also sometimes referred to as bit channels or subchannels. Placing bit values on bit indices as disclosed herein may also be referred to in other ways, such as placing bits or bit values on or at bit indices, bit positions, bit channels, or subchannels; or assigning bit values or bits to bit indices, bit positions, bit channels, or subchannels. Other terminology may be used to express how bit values or bits are provided as inputs to encoding. The present disclosure refers primarily to placement of bit values on bit indices, but other terminology may equivalently be used to convey the same concept.

In this way, a polar code may be considered as providing or comprising bit indices, bit positions, bit channels, or subchannels for bit values. Those bit indices, bit positions, bit channels, or subchannels are not necessarily only for bits that are to be encoded. For example, the u vector elements u, . . . u_{N} are also referenced in decoding, and therefore bit values that are decoded may similarly be associated with bit indices, bit positions, bit channels, or subchannels.

On the right side in FIG. 5, the code vector x also includes a number of elements that are in or at bit positions or bit indices. A bit value on the i-th bit index in the input vector u has some effect on multiple code bits in the code vector x, but the bit value on the i-th bit index in the input vector u is the primary contributor to the value of the code bit on the corresponding i-th bit index in the code vector x. In this sense, for a polar code, input vector bit indices or bit positions may be considered to correspond to, or be associated with or related to, code vector bit indices or bit positions. This is the case for polar codes, and there may be different input/code bit correspondence, relationships, or associations for other types of codes.

Regarding encoding, the process of encoding may be expressed in any of various ways. For example, encoding may be described as encoding bits to obtain encoded bits or to generate encoded bits. The above-referenced encoding process

$${x}_{1}^{N} = {u}_{1}^{N} {G}_{N} ,$$

for example, may De expressed as generating or otherwise obtaining an encoding input (the input vector u in this example) that includes bits or bit values for encoding, to obtain or generate a number of encoded bits (the code vector x in this example).

The bit values of elements in the input vector u, from an encoding perspective, may be referred to as values or bits to be encoded, or as values or bits for encoding, for example. Blocks of bits or bit values for encoding are also sometimes referred to as code blocks. The bit values of elements in the code vector x may be referred to as encoded bits, coded bits, or code bits, and a block of such bits may be referred to as a codeword, for example.

From a decoding perspective, decoding may be referred to as decoding encoded bits, a codeword, or a code, or as decoding, obtaining, or recovering bits or bit values (that were encoded), from the encoded bits, a codeword, or a code, for example. The bit values of elements in the vector u, in the context of decoding, may be referred to as decoded or recovered bits or bit values.

Successive cancellation (SC) is the basic decoding algorithm for polar codes, according to which all frozen bits and information bits are decoded sequentially, bit by bit. Preceding bits are always decoded first, before decoding a current bit.

Successive cancellation list (SCL) is an enhanced decoding algorithm for polar codes, where multiple (L) SC decoding instances are executed. Each instance is called a “decoding path”. When decoding each binary bit, both “0” and “1” branches are extended to each path, creating 2L paths. Then, all 2L paths are compared, where the most likely L paths are kept, and the least likely L paths are discarded (or pruned). The path extension and pruning operations are performed during decoding every information bit, until all information bits are decoded. At last, the most likely path is selected as the decoding output.

Cyclic redundancy check (CRC)-aided successive cancellation list (CA-SCL) decoding works almost the same as SCL, except that in the last step, the most likely path that passes CRC check is selected as the decoding output.

Parity-check successive cancellation list (PC-SCL) decoding also works almost the same as SCL, except that when decoding parity-check (PC) bits, the parity check value of associated preceding bits is used as a bit decision result. PC bits are in addition to frozen bits and information bits.

Rate-compatible polar coding is a key technology for wireless applications. One key characteristic of polar codes is that the actual reliability (or bit correct decoding probability) of polarized subchannels is governed by channel output quality of all code bits. In the case of rate matching, some of the channel outputs are completely unknown (for punctured bits) or completely known (for shortened bits, which are not transmitted but are known). As a result, actual subchannel reliability will change dramatically according to any puncture patterns (which may also or instead be referred to as puncturing patterns) and/or shorten patterns (which may also or instead be referred to as shortening patterns). By definition of polar codes, the K information bits should be placed on the K most reliable polarized subchannels. If not, significant performance degradation will be observed.

In the 5G NR standard (see 3rd Generation Partnership Project (3GPP), “Multiplexing and channel coding,” 3GPP 38.212 V.15.3.0, 2018), a combination of puncturing, shortening, and repetition is used together with a fixed reliability sequence to balance performance and complexity. In particular, a subblock-wise interleaving, which may also be referred to as interlacing, is used for both puncturing and shortening. The puncturing and shortening patterns are complementary and, together, form a symmetric (with respect to a polar code sequence) rate matching scheme.

With mother code length N, and code length M, the specific rate matching scheme used in 5G NR is as follows:

$$Repetition , when M > N ;$$

$$Puncturing , when K / M \leq 7 / 16 ;$$

$$Shortening , when K / M > 7 / 16.$$

Subblock-wise interleaving is performed before puncturing and shortening. An interleaver partitions the length-N mother code into 32 subblocks of size N/32 and interleaves them. Puncturing is performed from the first bit of a codeword, also referred to herein as a code bit, a coded bit, or an encoded bit, and shortening is performed from the last code bit. A rate matching module is efficiently implemented through a cyclic buffer. All mother code bits are placed in the cyclic buffer, puncturing is done by selecting the bits in clockwise order, and shortening is done by selecting bits in counter-clockwise order.

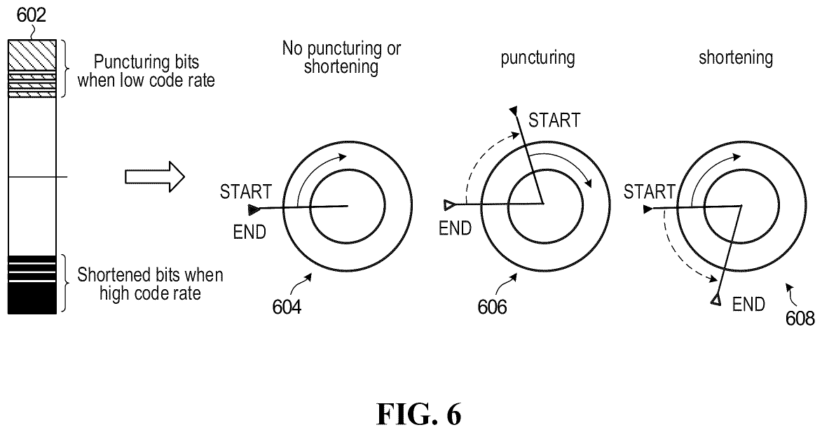

FIG. 6 is a diagram illustrating puncturing and shortening with a cyclic buffer. At 602 in FIG. 6, code bits of a codeword are illustrated in a vertical column, with punctured and shortened bits as shown. At 604, FIG. 6 illustrates a cyclic buffer, represented by a circle shape, and reading of code bits with no puncturing or shortening. The next two circles illustrate, respectively, cyclic buffers with dashed lines representing puncturing from the beginning of the buffer at 606 and shortening from the end of the buffer at 608.

In an incremental freezing HARQ method, transmissions of multiple short code words are supported. See B. Li, D. Tse, K. Chen and H. Shen, “Capacity-achieving rateless polar codes,” 2016 IEEE International Symposium on Information Theory (ISIT), 2016, pp. 46-50, doi: 10.1109/ISIT.2016.7541258. As more short codes are transmitted, the overall code length increases, and the overall code rate decreases.

In the first transmission, an (M₁, K) polar code is constructed, encoded and transmitted. The code rate is R₁=K/M₁, and is usually determined such that R₁<C₁, where C₁ is the channel capacity of the first transmission. In the case of faded channel or inaccurate channel estimation, it may be that R₁>C₁, and decoding will fail and a second transmission is required. In the second transmission, K₂ least reliable information bits are selected from the K information bits in the first transmission. In practice, K₂ is chosen according to the estimated channel capacity of the second transmission. An (M₂, K₂) polar code is constructed accordingly and encoded and transmitted. However, if R₂>C₂, decoding will fail again and a third transmission is required. The third transmission, and possibly further subsequent transmissions, are constructed similarly. For example, code length may be the same for up to four transmissions (M₁=M₂=M₃=M₄=16), with K₁=12, K₂=6, K₃=4, and K₄=2.

At the receiver side, it is expected that a decoder will always decode at least the last received codeword, because it has the lowest code rate and thus the best chance of successful decoding. After the last transmission is correctly decoded, the corresponding information bits in all previous transmissions become known, and can be decoded as frozen bits with known values. This process is repeated as more codewords are decoded, until all K bits in the first transmission are decoded. The term “incremental freezing” refers additionally freezing some information bits in previous transmissions once a later transmitted codeword is decoded.

In the 5G NR standard, PC polar codes were adopted to increase the minimum code distance of the original polar codes. Values of PC bits are determined by their preceding information bits, and specifically, binary linear combinations of a subset of preceding information bits. In one proposal of PC polar codes to support IR-HARQ, PC bits are for coupling multiple retransmissions into a longer polar code with extra coding gain. See M.-M. Zhao, G. Zhang, C. Xu, H. Zhang, R. Li and J. Wang, “An Adaptive IR-HARQ Scheme for Polar Codes by Polarizing Matrix Extension,” in IEEE Communications Letters, vol. 22, no. 7, pp. 1306-139 July 2018, doi: 10.1109/LCOMM.2018.2825370.

PC functions currently used for IR-HARQ are also a special case, where some information bits are copied from an initial transmitted code block to a retransmitted code block. This one-to-one parity checking between the two shorter code blocks effectively couples the two code blocks into a longer code block.

Consider an example, for an initial transmission of an (M₁=8, K=5) polar code, where {u₁₀, u₁₁, u₁₂, u₁₃, u₁₄} is the information set, and {u₅, u₆, u₇} is the frozen set. In this example, bit indices are in decreasing order of reliability. In a first retransmission, four additional code bits are transmitted. These four bits are coupled with the initially transmitted 8 bits to form an (M₂=12, K=5) polar code. The coupling is achieved by copying the value of u₄ to us during encoding, thus generating a PC function u₄+u₈=0 (or equivalently u₈=u₄). The largest index in this PC function corresponds to the PC bit (here u₈). During decoding, u₄ is decoded as an information bit, while us is decoded as a PC bit using u₈=u₄. In this example, {u₀, u₁, u₂, u₃, u₈} is the information set, {u₄} is the PC set, and {u₅, u₆, u₇, u₉, u₁₀, u₁₁} is the frozen set. In a second retransmission, four more additional code bits c₁₂, c₁₃, c₁₄, c₁₅ are transmitted to form an (M₃=16, K=5) polar code, but in this second retransmission no new PC bits are generated.

These existing rate matching and PC polar coding schemes can provide some flexibility. However, these schemes do not provide the “rateless” coding.

Rateless codes are channel codes that encode K source bits into a potentially very long encoded bit sequence with length Nₘₐₓ. A transmitter may incrementally transmit the bit sequence, until a receiver can successfully decode the source bits, and instructs the transmitter to stop further transmissions. The number of actually transmitted and received code bits may be denoted by M, and M<Nₘₐₓ. Thus, the code rate is R=K/M. In practice, the code rate R depends on code length M. The code length M depends on dynamic channel quality, because generally, a lower quality channel will require more transmissions and lower code rate for successful decoding. The term “rateless” comes from the fact that an encoder does not determine the code rate R before transmission. In other words, the code rate R is not fixed in advance, but adapts to channel state. When channel quality is high, R is higher; and when channel quality is low, R is lower.

Hybrid automatic repeat request (HARQ) is a mechanism to provide reliable wireless transmission. It combines forward error correction (FEC) and automatic repeat request (ARQ). In HARQ, an initial transmission is a FEC codeword with CRC bits to support error detection at a receiver. If a decoding error is detected, then the receiver will send negative acknowledgement NACK signaling to the transmitter, to inform the transmitter of the error and request for a retransmission. Retransmitted bits can be directly selected from the initially transmitted bits, or the retransmitted bits can be incrementally generated code bits which form a longer codeword with the initially transmitted bits. The former retransmission approach is called chase-combining HARQ (CC-HARQ) and the latter approach is called incremental-redundancy HARQ (IR-HARQ). Typically, IR-HARQ outperforms CC-HARQ due to the additional coding gain resulting from the incremental redundancy.

With rateless codes, IR-HARQ can be conveniently designed. In 5G LDPC codes, a Raptor-code-like structure was adopted to support ratelessness. Before transmission, the encoder generates the maximum-length N mother codeword regardless of the actually transmitted length M. For the initial transmission and subsequent retransmissions, the transmitter simply selects a subset of the mother code bits. Although some current rate matching and PC-polar coding schemes can achieve some flexibility and support HARQ in some ways, achieving rateless IR-HARQ remains a challenge.

In 5G polar code rate matching, for example, the transmitted code length M must be known before code construction. First, an encoder will determine whether to puncture or shorten the code according to M, and then the information set I is selected according to the puncturing/shortening pattern(s). This fixing of code length M before code construction violates the definition of ratelessness. Moreover, the 5G polar code rate matching scheme does not support multiple transmissions. When there are potentially multiple transmissions including an initial transmission and one or more retransmissions, the code construction is unknown.

The incremental freezing IF-HARQ scheme referenced above supports multiple transmissions, but both the code length Mᵢ and information length Kᵢ in each retransmission need to be known at the transmitter before constructing retransmitted codewords. Specifically, the values of Mᵢ and Kᵢ for a retransmission are determined by a channel estimation result for that transmission. Correspondingly, an (Mᵢ, Kᵢ) polar code must be constructed for each retransmission. Again, this approach involves predetermination of code rates and violates the definition of ratelessness. Another drawback is its inferior coding gain compared to that of a long code. For example, the combined performance of the first two codewords (M, K) and (M₂, K₂) is still worse than a long codeword (M+M₂, K).

The above-referenced proposal of PC polar codes to support IR-HARQ also supports multiple transmissions, but the code length Mᵢ in each retransmission needs to be known at the transmitter before constructing codewords, which also violates the definition of ratelessness. Specifically, the value of Mᵢ determines the number of copied bits (or PC bits) in each retransmission. Because the resulting code construction depends on the number of transmitted bits in each transmission, complexity becomes high and flexibility becomes low. Moreover, the performance after two retransmissions is inferior to a long codeword (M+M₂, K).

Some embodiments disclosed herein are directed to providing IR-HARQ based on rateless polar codes. Flexibility, simplicity, and coding gain are desirable features for IR-HARQ. All three of these features are related to ratelessness, which was not available for the foregoing examples of polar codes. With ratelessness, code length M of a given information length K is not pre-determined, and a retransmission or incremental transmission is transmitting not-yet-transmitted bits that have not been included in other transmissions, such as previous transmissions. An arbitrary number of retransmissions or incremental transmissions with an arbitrary number of bits is possible. The above-referenced U.S. provisional patent application Ser. No. 63/454,067 entitled “Methods, Systems, and Apparatus for Rateless Polar Coding” and Ser. No. 63/454,068, entitled “Methods, Systems, and Apparatus for Rateless Polar Coding and Low-complexity Decoding”, for example, provide rateless polar codes that may facilitate new polar codes supporting IR-HARQ.

For polar codes, the bit vector before polar encoding includes known bits (frozen bits) and unknown bits (information bits, possibly copied bits, possibly PC bits, possibly CRC bits, and so on). In prior approaches to polar coding, bit positions of the known bits and unknown bits are adjusted for each transmission according to the transmitted encoded bit positions. The adjusting process is actually a code construction process, and has to be performed before every transmission or retransmission based on the transmission or retransmission lengths. This may be referred to as, for example, “construct→transmit→reconstruct→retransmit→ . . . ”, wherein reconstruction is performed before each retransmission. Specifically, for each retransmission, bit indices that are to be retransmitted are taken into account in code reconstruction to determine bit indices for encoding, which may be expressed as follows: {retransmitted bit indices}→code reconstruction module→ {known/unknown bit indices}

In the present disclosure, the bit positions of the known bits and unknown bits are pre-determined or determined in the very beginning, for a maximum mother code length, and do not depend on transmitted encoded bit positions, or the transmission or retransmission lengths of each transmission or retransmission. This may be referred to or expressed as follows, for example: “construct→transmit→retransmit→ . . . ”. Specifically, no code reconstruction is performed for each retransmission. Retransmitted bits are associated with known and unknown bit positions that are determined once, before the initial transmission, for that initial transmission and all transmissions. Thus, according to embodiments herein, input bit are encoded by a polar code to obtain encoded bits, and numbers of those encoded bits are output (and may be transmitted, for example) in incremental outputs or transmissions. There is no code reconstruction before each output or transmission, but rather encoded bits for each output or transmission are selected or otherwise determined from the encoded bits that are obtained by encoding the input bits only once.

Another technical problem that may be addressed by some embodiments herein relates to IR-HARQ protocols for polar codes. For rateless polar codes, IR-HARQ protocols may need to be specified, including one or more parameters or characteristics such as any one of: cyclic buffer design, starting points of redundancy versions (RVs), a maximum number of polar transformation matrix extensions, etc. A new encoding chain may be used to specify an entirety of encoding in a standard-friendly way.

Although embodiments are described herein by way of example with reference primarily to transmitting encoded bits, outputting encoded bits may involve transmitting encoded bits, or encoded bits that are output may be transmitted, but it should be appreciated that not all embodiments necessarily involve transmitting encoded bits. Features that are disclosed herein in the context of transmitting encoded bits may be applied more generally to outputting encoded bits.

Similarly, although some embodiments refer to circular transmission or output, “circular” is not in any way limited to managing code bits using a circular buffer. Transmitting or outputting code bits may be circular, regardless of whether a circular buffer is used, at least in the sense that code bits may be repeated starting from an initial starting position of an initial transmission or output, after all code bits for a maximum mother length code have been transmitted. Features disclosed herein are not limited to circular buffer implementations, or to embodiments that necessarily involve repeating code bits after transmitting or outputting code bits for a maximum mother code length.

The present disclosure also refers to transmissions and retransmissions. It should be appreciated, however, that this is also intended to be illustrative and non-limiting. For example, multiple redundancy versions (RVs) need not necessarily be transmitted in sequential transmissions, but can be transmitted all at once, on multiple channel resources (e.g., multiple different multiple-input multiple-output (MIMO) layers, multiple slots (“multi-slot”), multiple physical resource blocks (PRBs) or “multi-PRB”, multiple carriers (“multi-carrier”), etc.) for example. Each RV may be self-decodable if only that RV is received for example, and may also be jointly decodable to provide soft combining coding gain if multiple RVs are received. The terms transmission and retransmission encompass not only sequential transmissions, but also concurrent or overlapping (in time) transmissions.

Embodiments disclosed herein may integrate aspects of one or more of the related applications referenced above. For example, some embodiments may integrate features related to any of the following: non-sequential decoding for polar codes, placement of input bit values on multiple bit indices, partial code rate reduction, partially interleaved encoded bit reduction, and rateless polar codes.

Several features related to rateless polar IR-HARQ are introduced briefly below, and then discussed in further detail.

Regarding code construction, for an information length K, encoding may be according to a rateless polar code of maximum mother code length N and minimum mother code length N₀. There are several options to determine N₀, including the following illustrative and non-limiting examples:
Minimum mother code length N₀ is determined as the largest power of 2 number that is smaller than K, i.e., N₀=2^{└log}^{₂} ^{K┘}, where └°┘ is a floor function. A potential benefit of this approach to determining N₀ is unified rate matching between an initial transmission and retransmissions for better performance.
Minimum mother code length N₀ is determined as the smallest power of 2 number that is larger than K, i.e., N₀=2^{┌log}^{₂} ^{K┐}, where ┌°┐ is a ceiling function. A potential benefit of this approach to determining N₀ is that rate matching for an initial transmission can reuse existing rate matching schemes (e.g., according to 5G NR) for backward compatibility.
Minimum mother code length N₀ is determined as the largest power of 2 number that is smaller than an initial transmission length M₀, i.e., N₀=2^{└log}^{₂} ^{M}^{₀}^{┘}. A potential benefit of this approach to determining N₀ is unified rate matching between an initial transmission and retransmissions for better performance, yet with lower complexity because code construction for M<N₀ is simplified.
Minimum mother code length N₀ is determined as the smallest power of 2 number that is larger than the initial transmission length M₀, i.e., N₀=2^{┌log}^{₂}^{M}^{₀}^{┘}. A potential benefit of this approach to determining N₀ is that rate matching for an initial transmission can reuse existing rate matching schemes (e.g., according to 5G NR) for backward compatibility, yet with lower complexity because the code construction for M<N₀ is simplified.

There are also several options to determine maximum mother code length N, including the following illustrative and non-limiting examples:
Maximum mother code length N is determined as a pre-defined maximum mother code length, which may be specified by a communication standard for example. A selection may be made between a number of pre-defined code lengths, such as 1024, 2048, 4096, 8192, 16384, 32768, 65536, which are illustrative examples. One reason to adopt a pre-defined maximum mother code length approach is in consideration of both hardware limitations and coding applications. For example, for control channels the maximum mother code length may be 1024 or 2048. For data channels, the maximum mother code length may be 4096, 8192, 16384, 32768, 65536. In selecting from these code lengths, if the application is ultra-high-throughput transmission, a smaller maximum mother code length may be preferred, e.g., 1024, 2048, even for a data channel.
Maximum mother code length N is determined as a pre-defined power of 2 multiple of the minimum mother code length N₀, such as 2·N₀, 4·N₀, 8·N₀, 16·N₀, 32·N₀, 64·N₀, 128·N₀, for example. The multiple number corresponds to the maximum number of generator matrix (or polar transformation matrix) extensions from a current code length to twice that code length in iterative or recursive code construction. This can be beneficial, for example, when communication devices have their own respective hardware resource limits and maximum mother code length can be defined accordingly.

In some embodiments, IR-HARQ transmissions or more generally outputs of code bits are managed using a circular buffer. This is an illustrative example, and other implementations are possible.

The N code bits of a maximum mother code length codeword may be placed in a circular buffer with circumference or size N. In each transmission or output, which may be referred to as a redundancy version (RV), code bits in the circular buffer are transmitted or otherwise output from the circular buffer in a pre-defined order, which may be clockwise or counter-clockwise.

The circular buffer is read out in reverse order from the last, highest-index code bit (i.e., the N-th bit) in some embodiments. If the code bits in the circular buffer are indexed by [1, 2, 3, . . . , N], then the read-out order is by bit index in the following order in this example: [N,N-1, . . . , 2, 1]. The starting point for output from the entire circular is N and the ending point is 1 in this example. Once the transmission or output reaches the ending point, the circular buffer is again read from the starting point until the required number of bits are transmitted or output.

Code bits and/or a circular buffer may be divided or partitioned into several segments in some embodiments, of sizes N/2, N/4, . . . , N₀, N₀ from the first bit onward for example. Any segment(s), or each segment, may be further divided or partitioned into sub-segments or blocks, such as D equal-sized blocks, where D is power of 2, e.g., 2, 4, 8, 16, 32, 64, 128.

Each RV may be associated with a starting point (also referred to herein as a starting position) and an ending point (also referred to herein as an ending position), where code bits starting from the starting point and ending at the ending are transmitted or otherwise output. There are several options regarding starting points and ending points and managing output of code bits.

According to an approach that is referenced herein as circular continuous transmission or output, the starting point for a next RV is the next position or index from the ending point of the previous (immediately preceding) RV. For a reverse readout order, the starting point of RV0 is N, and the ending point of RV0 is N−M₀+1, where M₀ is the length of RV0. The starting point of RV1 in this example is N−M₀, and the ending point of RV1 is N−M₀−M₁₊₁, where M₁ is the length of RV1, and so on. More generally, the starting point of RVi (for i>0) is N−M₀- . . . Mᵢ₋₁, and the ending point of RV1 is N−M₀- . . . Mᵢ₋₁−Mᵢ₊₁, where Mᵢ is the length of RVi. If the starting point or ending point X is larger than N, then a modular operation may be applied: X=mod (X, N).

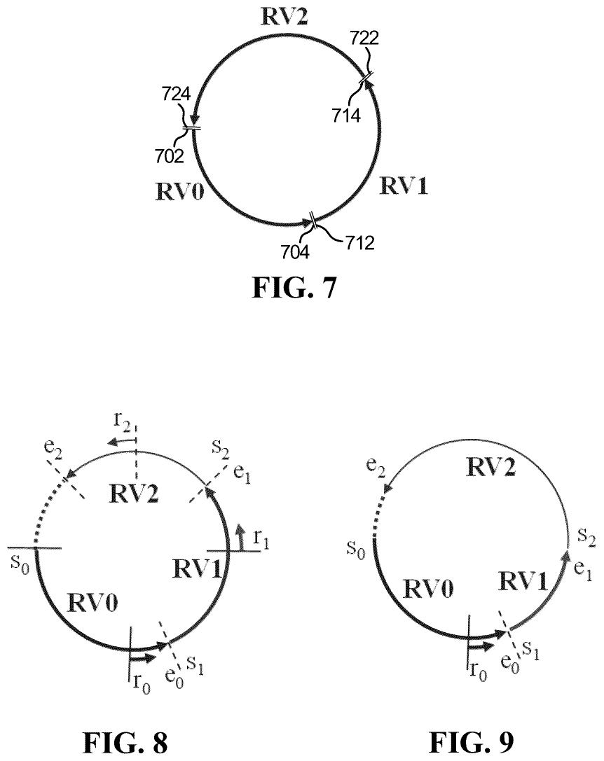

FIG. 7 is a diagram illustrating starting and ending points for output from a circular buffer according to a circular continuous transmission or output embodiment. The example shown is for three RVs, which have a combined length that matches the length of a circular buffer. In FIG. 7, 702, 704 designate the starting point and ending point of RV0; 712, 714 designate the starting point and ending point of RV1; and 722, 724 designate the starting point and ending point of RV2.

Another approach is referenced herein as circular transmission or output with repetition. Circular read out is similar to the circular continuous approach, except that starting points and ending points are chosen from a pre-defined position set or index set. The elements of a position set are starting points and ending points of blocks into which each segment is divided or partitioned, denoted by [sb₀, s_{b1}, s_{b2}, . . . ] and [e_{b0}, e_{b1}, e_{b2}, . . . ], respectively, for ease of reference. Put another way, each RV includes bits, for transmission or output, between a starting point in [s_{b0}, s_{b1}, s_{b2}, . . . ] and an ending point in [e_{b0}, e_{b1}, e₂, . . . ].

If transmitting or outputting Mᵢ bits for RVi leads to an ending point that is inside a block rather than at the ending point of the block, then no bits from that block are transmitted or output, which is unlike in the circular continuous transmission or output approach. The ending point for the RV is instead set to be the ending point of the previous (immediately preceding) block, denoted by e_{bj}. If the starting point for the RVi is denoted by sᵢ, then a direct consequence of setting the ending point in this manner is that the number of code bits to be transmitted or output between s; and e; (where the RVi ending point e; is set to the block ending point e_{bj} in this example) is fewer than Mᵢ, or using the notation introduced above, (eᵢ−sᵢ+1)<Mᵢ.

In order to ensure that Mᵢ code bits are transmitted or output in RVi, some of the code bits between sᵢ and eᵢ are repeatedly transmitted or output. In some embodiments, a starting point for repetition of code bits in RVi, denoted by rᵢ, is specified and used to manage repeated transmission or output of code bits in an RV. To achieve good performance, the starting point s_{bj} of the previous block (with ending point e_{bj}) is adopted as the repetition starting point rᵢ for RVi. Code bits starting from rᵢ (=s_{bj} in this example), which may have already been transmitted or output or otherwise included in another (re)transmission or output, are repeated until the total number of transmitted or output code bits in RVi is Mᵢ.

FIG. 8 is a diagram illustrating output of bits from a circular buffer according to an embodiment of circular transmission or output with repetition. Starting points and ending points (reset to preceding block ending points) for each of three RVs are s₀, s₁, s₂ and e₀, e₁, e₂, respectively, and starting points r₀, r₁, r₂ fore code bit repetition are also shown. The dashed line between e₂ and s₀ is intended to illustrate that there may be more than three RVs, and more generally there may be more or fewer than three RVs. In order to avoid further congestion in the drawing, segmentation is not shown, and also RV starting and ending points are shown as labels next to respective single dashed lines instead of multiple lines as in FIG. 7.

Regarding notation, the sᵢ, eᵢ, and rᵢ labels in FIG. 8 are associated with the RVs. The starting points, ending points, and repetition starting points designated by these labels in FIG. 8 also correspond to starting or ending points of blocks into which segments of code bits are partitioned or divided. The blocks within any individual segment are preferably of the same size, but different segments may have different sizes, and blocks within different segments may have different sizes.

For example, so is the starting point of RV0, but that starting point is also the starting point of a block (s_{bj}) within a segment, and the starting point of a segment (sₛₖ). The repetition starting point r₀ for RV0 is the starting point of a block within a segment, and may or may not also be the starting point of another segment. The reset ending point e₀ of RV0 is the ending point of the block that has the same starting point as the repetition starting point r₀, and may or may not also be the ending point of a segment. Similarly, the RV1 starting point s, is also the starting point of a block and may or may not also be the starting point of a segment, the RV1 repetition starting point r₁ is the starting point of another block and may or may not also be the starting point of a segment, and the RV1 ending point e, is also the ending point of block and may or may not also be the ending point of a segment. Finally, for the example shown, the RV2 starting point s₂ is also the starting point of a block and may or may not also be the starting point of a segment, the RV2 repetition starting point r₂ is the starting point of another block and may or may not also be the starting point of a segment, and the RV2 ending point e₂ is also the ending point of block and may or may not also be the ending point of a segment.

The block size between r₀ and e₀ is intentionally shown to be a different size from the block between r₁ and e₁, to illustrate that block sizes may be different, for blocks that are parts of different segments for example.

For circular transmission or output with repetition, suppose that M₀>(e₀−s₀), so that RV0 would end within the block that has a starting point coinciding with s₁. As outlined above, this would lead to an ending point that is inside a block rather than at the ending point of the block, in which case no bits from that block with the starting point coinciding with s₁ are transmitted or output. The ending point for RV1 is instead set to e₀, which is also the ending point e_{bj} of the previous (immediately preceding) block. The starting point of block j (s_{bj}) is used as the repetition starting point r₀ for repeating transmission or output of code bits so that M₀ code bits are transmitted or output in RV0. Transmission or output of code bits for RV1 and RV2 proceeds similarly, based on the number of code bits to be transmitted or output, block starting points, and block ending points.

The selection of a starting point sᵢ, an ending point eᵢ, and a repetition starting point rᵢ of an RVi are determined by or based on segmentation, block partitioning, and transmission or output length Mᵢ.

For polar codes, code lengths that are a power of 2, or a sum of several power of 2 numbers, may generally be preferred. It may therefore be preferable to transmit or output a power of 2 number of code bits in any RV before repeating bits, rather than transmitting or outputting more than a power of 2 number of code bits that have not previously been transmitted or output or otherwise included in another (re) transmission or output. Potential benefits of power of 2 transmission or output include: simpler scheduling and lower complexity decoding due to less frequent switching between sequential decoding and non-sequential decoding of code bits, and more stable performance because negative decoding impact of transmitting or outputting a number of code bits exceeding a power of 2 number are avoided.

Regarding decoding, code bits obtained by polar code encoding are typically decoded sequentially, bit by bit, in order of bit index. The above-referenced PCT Application No. PCT/CN2023/083350, for example, discloses non-sequential decoding of polar codes, and some embodiments herein may provide or support non-sequential decoding of at least some code bits. For example, one or more subsets of code bits may be decoded sequentially, and one or more other subsets of code bits may be decoded non-sequentially, with decoding switching one or more times between sequential and non-sequential decoding. Power of 2 transmission or output as disclosed herein may lead to switching less often during decoding.

Another embodiment is referred to herein as circular transmission or output with conditional repetition. This embodiment provides or supports features of both circular continuous transmission or output and circular transmission or output with repetition, and selection between those features depending on one or more conditions. In general, when overall code rate is high, starting and ending transmission or output at pre-defined positions (as in circular transmission or output with repetition) may be preferred, to help avoid performance degradation. When the overall code rate is lower, arbitrary starting and ending points as in circular continuous transmission or output may provide similar performance but enjoy lower complexity. Examples of conditions based upon which a selection may be made between different transmission or output approaches include those described below.

Selection may be based on code rate before, or preceding code rate: If the code rate before a current RVi is larger than a threshold Rₜₕ, which may be expressed as K/(M₀+M₁+ . . . +Mᵢ₋₁)>Rₜₕ, then select an ending point for RVi from a pre-defined set [e₀, e₁, e₂, . . . ], according to circular transmission or output with repetition. Otherwise, set the ending point according to circular continuous transmission or output, to transmit or output the next Mᵢ bits in the circular buffer without repetition.

Another selection condition or criterion is based on code rate after, or subsequent code rate: If the code rate after the current RVi is larger than a threshold Rₜₕ, which may be expressed as K/(M₀+M₁+ . . . +Mᵢ)>Rₜₕ, then select an ending point for RVi from a pre-defined set [e₀, e₁, e₂, . . . ], according to circular transmission or output with repetition. Otherwise, set the ending point according to circular continuous transmission or output, to transmit or output the next Mᵢ bits in the circular buffer without repetition.

A selection condition may be related to RVs. RV index is another example condition or basis for selection: If the RV index i of the current RVi is smaller than a threshold iₜₕ, which may be expressed as i<iₜₕ, then select an ending point from a pre-defined set [e₀, e₁, e₂, . . . ], according to circular transmission or output with repetition. Otherwise, set the ending point according to circular continuous transmission or output, to transmit or output the next Mᵢ bits in the circular buffer without repetition. Here, it can be 1, 2, 3, 4 in embodiments that involve an initial transmission and 4 (or more) retransmissions.

This type of RV index condition may be most appropriate in embodiments that involve RVs being transmitted or output in sequential order of RV indices, for example with RV0 being transmitted or output first, then RV1 being transmitted or output, and so on. However, this might not necessarily be the case in all embodiments. RV transmission or output need not necessarily be in order of RV index. RV number or order, referring to the order in which RVs are transmitted or output, is another example of a selection condition that is based on the RV that is associated with a transmission or output. According to an embodiment, if the current RV is below or before a threshold in the number or order of transmissions or outputs, then an ending point is selected from a pre-defined set [e₀, e₁, e₂, . . . ], according to circular transmission or output with repetition; and otherwise, the ending point is set according to circular continuous transmission or output, to transmit or output the next Mᵢ bits in the circular buffer without repetition. The number or order threshold may be 1, 2, 3, 4 in embodiments that involve an initial transmission and 4 (or more) retransmissions, for example.

Block position in a segment may be used as a selection condition or basis. Some embodiments involve each segment in a circular buffer being further divided or partitioned into blocks, or more generally a circular buffer being divided or partitioned into blocks. With D blocks, for example, the blocks may be indexed by [1, 2, . . . , D] according to transmit or output order in the circular buffer.

As an example, consider segmentation that aligns with or corresponds to mother code lengths, and division or partitioning of segments into blocks. If an RV has a length that would end in the first block of a next segment, then stopping transmission or output of new code bits for that RV and instead repeating one or more code bits as disclosed herein corresponds to transmitting over a mother code length because code bits for the mother code length have already been transmitted or output before transmission or output of the additional repeated code bit(s). Similarly, if an RV has a length that would end in the last block of a current segment, then stopping transmission or output of new code bits for that RV and instead repeating one or more code bits as disclosed herein corresponds to transmitting under, or short of, a mother code length because not all code bits for the mother code length have not been transmitted or output before transmission or output of the additional repeated code bit(s). The former case (stopping in the first block) may lead to performance degradation, and the latter case (stopping in the last block) may have no significant performance loss.

Selection based on block position involves selection between circular transmission or output with repetition and circular continuous transmission or output according to the block index d in a segment. For example, if d≥dₜₕ then select or adopt circular transmission or output with repetition, and otherwise select or adopt circular continuous transmission or output. In this example, where di is a threshold, such as D/2.

A block position condition need not necessarily involve a threshold. As another example, if d is an even number then select or adopt circular transmission or output with repetition, and otherwise if d is an odd number then adopt circular continuous transmission or output. A more general version of this odd/even condition or rule can be expressed as follows: if d modulo D₀ is D₀−1 (d mod D₀=D₀−1) then adopt circular transmission or output with repetition, and otherwise adopt circular continuous transmission or output. Here, D₀ is a power-of −2 smaller than or equal to D.

These examples can be combined to create more accurate or comprehensive conditions. For example:
if the code rate (before or after) the current RVi is larger than a threshold, AND d≤dₜₕ then select or adopt circular transmission or output with repetition, and otherwise select or adopt circular continuous transmission or output;
or
if the RV index i of the current RVi is smaller than a threshold, i.e., i≤iₜₕ, AND dis an odd number then select or adopt circular transmission or output with repetition, and otherwise select or adopt circular continuous transmission or output.

FIG. 9 is a diagram illustrating output of bits from a circular buffer according to an embodiment of circular transmission or output with conditional repetition. In the example shown, circular transmission or output with repetition is selected or adopted for RV0, whereas circular continuous transmission or output is selected or adopted for RV1 and RV2.

These illustrative embodiments, and others, are considered in further detail below.

### Illustrative Embodiment 1—Circular Continuous Transmission or Output

For ease of reference, circular continuous transmission or output is also referred to herein as Embodiment 1.

As an example, minimum mother code length is denoted N₀ as above, and maximum mother code length is N₂=2²×N₀=4×N₀. This maximum mother code length may be constructed in an iterative or recursive manner, by extending an N₀-by-N₀ polar transformation matrix twice, to an N₂-by-N₂ polar transformation matrix. An intermediate mother code length after one extension may be denoted N₁=2×N₀.

In some embodiments, the maximum length mother code is divided into several segments, of sizes N₂/2, N₂/4, N₂/4 (or equivalently N₁, N₀, N₀), for example. The first two segments may be interleaved, which may involve each of the first two segments being separately interleaved in some embodiments, by interleavers: π₁ and π₂.

This type of interleaving may be referred to as partial interleaving, because interleaving is applied only to part of a codeword or to some but not all code bits. Partial interleaving involves interleaving fewer than all code bits, or in other words is interleaving other than full-interleaving.

Partial interleaving may involve one or more block interleavers for example, with a width and a height of the interleaver blocks both being a power of 2 in some embodiments. Power of 2 block dimensions may be particularly preferred in conjunction with code lengths that are also a power of 2, such as codes derived from a power of 2 length mother code.

In the context of code bits or code bit indices being divided into multiple segments or subsets, one or more of those segments or subsets is not interleaved, or at least is not interleaved for the purpose of encoded bit reduction as referenced at least below, and one or more of the other segments or subsets is interleaved.

Interleaving, as used herein in the context of disclosed embodiments, refers to changing an order of elements of a segment or subset. Interleaving is used primarily herein, but is intended to encompass such changing of order more generally, and may also or instead be referred to as shuffling, reordering, scrambling, interlacing, interweaving, etc. An interleaved segment or subset includes the same elements as a segment or subset before interleaving, but in a different order within the segment or subset.

Partial interleaving may be preferred in embodiments in which not all code bits are to be transmitted or otherwise output, as a result of reducing the number of code bits by rate matching, puncturing, or shortening for example. When combined with reducing the number of code bits, partial interleaving can provide for more accurate allocation of capacity to where it is needed the most. For segments or subsets of encoded bits of a codeword in which the number of encoded bits is not reduced, there is no need for interleaving. Full interleaving (e.g., as implemented in the 5G NR standard for example) will change the order of all encoded bits, and therefore puncturing will, in effect, apply to an entire codeword because an encoded bit that was originally at any position in a codeword may appear at a puncture position after interleaving. More targeted reduction in the number of encoded bits, by puncturing or otherwise, is preferable such that encoded bits are removed from only certain parts of a codeword, and accordingly only certain bit indices or parts of a code block have reduced capacity. Other codeword and code block parts are not adversely impacted, or at least are not adversely impacted as significantly. Put another way, only certain parts of a code or codeword are punctured, and it is preferable to restrict interleaving to those parts.

To summarize, a potential advantage of partial interleaving compared to interleaving all encoded bits is enabling more targeted and fine-tuned encoded bit reduction, such as via puncturing for example.

The segments or subsets that may be interleaved in the example above have sizes N₂/2, N₂/4 (or equivalently N₁, N₀). Other sizes or lengths are possible, but generally power of 2 lengths may be preferred.

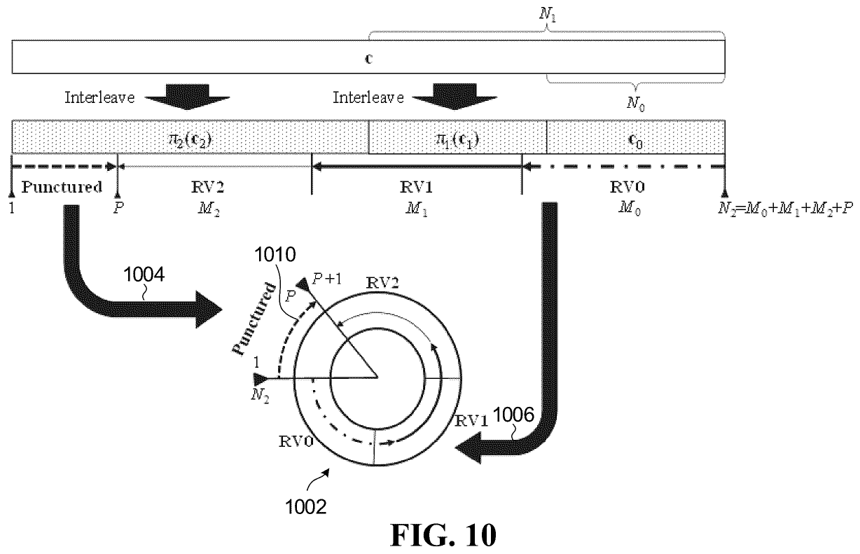

FIG. 10 is a diagram illustrating an embodiment that includes optional partial interleaving and puncturing. A codeword of length N₂ is denoted by c, and is divided or partitioned into three segments c₀ of length N₀=N₂/4, c₁ of length N₀=N₂/4, and c₂ of length N₁=N₂/2. With codeword c of length N, c₂=c[1, 2 . . . . N/2], c₁=c[N/2+1, N/2+2 . . . 3N/4] and c₀=c[3N/4+1, 3N/4+2 . . . . N]. The two segments or subsets c₂ and c₁ are interleaved into interleaved segments or subsets denoted by: π₂(c₂) and π₁(c₁), by interleavers: π₂ and π₁. The interleavers may be of the same or different types. As an example, both interleavers may be block interleavers, but of different sizes. In the example shown, the partial interleaving generates or provides a partially interleaved codeword c′=[π₂(c₂),π₁(c₁),c₀].

In practice, the bits in c′ can be sequentially written into a cyclic buffer. In FIG. 10, a cyclic buffer is shown at 1002, and the arrows 1004, 1006 are intended to represent sequentially writing: π₂(c₂), π₁(c₁), and c₀ into the cyclic buffer. Transmission or output starts at the N₂-th bit and proceeds counter-clockwise in the sense of the circular buffer 1002 in the example shown. With optional puncturing of P bits as shown at 1010, transmission or output proceeds to the (P+1)-th bit, or to the first bit if there is no puncturing. It should be noted however, that clockwise writing to a circular buffer, counter-clockwise reading from a circular buffer for transmission or output, and circular buffer-based implementation are all illustrative examples. A circular buffer may or may not be used, transmission or output may or may not be in the order shown in FIG. 10, and writing to memory for subsequent transmission or output may or may not be in the order shown. Also, as previously noted, segmenting, interleaving, and puncturing are optional.

Regarding order of transmission or output, for example, transmission or output may start at the (P+1)-th bit (or the first bit if there is no puncturing), and proceed clockwise in the sense of the circular buffer 1002, to the N₂-th bit.

In FIG. 10, c₂ is an example of a segment or subset of encoded bits in the codeword c. The segment or subset includes fewer than all of the encoded bits in c. The encoded bits in the subset c₂ are interleaved in this example, and the number of encoded bits in the interleaved subset: π₂(c₂) is reduced, by puncturing in the example shown. Thus, the segment or subset c₂ is, in at least this sense, for reducing the number of encoded bits. The reduced number of encoded bits may be output, for transmission for example.

FIG. 10 is illustrative of an embodiment in which there are multiple unique segments or subsets of encoded bits, which include fewer than all of the encoded bits, to be interleaved. In such an embodiment, the segments or subsets that are to be interleaved, together include fewer than all of the encoded bits, so that the interleaving remains partial interleaving even though multiple segments or subsets of encoded bits are interleaved.

FIG. 10 also provides an example in which code bits in more than one segment or subset are interleaved separately within each segment or subset. This type of interleaving can provide more flexibility in design space, and stable performance under different operating conditions.

Different types of interleaving are possible. Multiple types of interleavers or interleaving can be supported for partial interleaving. In block interleaving, for example, original code bits are written into and read from a block interleaver with RI rows (referring to the number of rows of the interleaver, RI) and CI columns (referring to the number of columns of the interleaver, CI). Either or both row-in write/column-out read and column-in write/row-out read may be supported.

Without loss of generality, partial code bits, which are encoded bits that are to be interleaved, may be written row-by-row and read column-by-column to obtain interleaved partial code bits. A number of rows RI, or a number of columns CI, or both, may be a power of 2. A power of 2 size for block interleaver rows and/or columns may be preferred for mother code lengths that are a power of 2, but other block interleaver sizes are possible.

With the partial code bits in c. (as an example) denoted c₁[1], c₁[2], . . . c₁[W], where W is the size of c₁ (which may also be referred to herein as a partial block or partial code bits) to which interleaving is to be applied, the interleaved partial code bits π₁c₁[1], π₁c₁[2], . . . . π₁c₁[W] may be generated according to the following example pseudocode:

```
For j=1 to W/RI
  For i=1 to RI
    π₁c₁[i+(j−1)*RI] = π₁c₁[j+(i−1)*(W/RI)]
  End for
End for
```

Each row and/or column may also or instead be permuted (or written/read in different orders). A permutation sequence for row and/or column permutation, in combination with block interleaving, can be generated or otherwise obtained according to, for example, a bit-reversal order or a pseudo-random order. The pseudo-random order may be specified, for example, by a polynomial, by a table, or by a transform such as a Fourier transform, a Hadamard transform, a discrete cosine transform, or a wavelet transform.

Another block interleaving example is based on the following 5G NR subblock interleaving, reproduced from 3rd Generation Partnership Project (3GPP), “Multiplexing and channel coding,” 3GPP 38.212 V.15.3.0, 2018:

TABLE 5.4.1.1-1
Sub-block interleaver pattern P(i)

| i | P(i) |
|---|---|
| 0 | 0 |
| 1 | 1 |
| 2 | 2 |
| 3 | 4 |
| 4 | 3 |
| 5 | 5 |
| 6 | 6 |
| 7 | 7 |
| 8 | 8 |
| 9 | 16 |
| 10 | 9 |
| 11 | 17 |
| 12 | 10 |
| 13 | 18 |
| 14 | 11 |
| 15 | 19 |
| 16 | 12 |
| 17 | 20 |
| 18 | 13 |
| 19 | 21 |
| 20 | 14 |
| 21 | 22 |
| 22 | 15 |
| 23 | 23 |
| 24 | 24 |
| 25 | 25 |
| 26 | 26 |
| 27 | 28 |
| 28 | 27 |
| 29 | 29 |
| 30 | 30 |
| 31 | 31 |

In 5G, the above 32-subblock interleaver is applied to an entire codeword of length N code. According to an embodiment, the 32-subblock interleaver may be reused, but applied only to a partial block. As code length is increased, the 32-subblock interleaver can be applied to the v-code at each stage or iteration.

For example, consider an initial output code length of M₀=128, with K=96 (code rate 3/4). The code length may be extended in multiple stages or transmissions, as follows for example:
1. M₁=256 (extending from length 128 to length 256), apply the 32-subblock interleaver to the length-128 v-code—each subblock has length 4;
2. M₂=512 (extending from length 256 to length 512), apply the 32-subblock interleaver to the length-256 v-code—each subblock has length 8;
3. M₃=1024 (extending from length 512 to length 1024), apply the 32-subblock interleaver to the length-512 v-code—each subblock has length 16;
. . . and so on-the final output code length can be very large, up to maximum mother code length.

Bit-reversed interleaving may be implemented with block interleaving, or may instead be implemented without block interleaving in some embodiments.

Suppose that W partial code bits are to be interleaved and bit indices of those code bits in a mother polar code are denoted by i₁, i₂ . . . i_{W}. Without loss of generality, further suppose that i₁, i₂ . . . i_{W} are in ascending order. This is just an example, and partial code bits to be interleaved need not be consecutive.

In an embodiment, bit-reversed interleaving may involve writing the partial code bits into an interleaver, with bit indices i₁, i₂ . . . i_{W} in ascending order. The numbers 0, 1 . . . . W−1 are associated to the partial code bits with indices i₁, i₂ . . . i_{W}, respectively. Bit-reversed values of 0, 1 . . . . W−1 are then calculated or otherwise determined, as BitRev(0), BitRev(1) . . . . BitRev(W−1). Interleaved partial code bits are then read out from the bit indices associated to the numbers BitRev(0), BitRev(1) . . . . BitRev (W−1), in that order.

The bit-reversed value of an integer x is obtained as follows. First, the integer x is converted into binary expansion form [b₀, b₁ . . . bₙ]. Then the binary expansion is reversed to [bₙ . . . b₁, b₀], and is converted into an integer y. Bit-reversal in this example may be denoted y=BitRev(x).

Embodiments are not in any way restricted to these specific types of interleavers or interleaving, to one single type of interleaving, or to applying any interleaving at all.

For the illustrative example in FIG. 10, code bits of the partially interleaved maximum length mother codeword are placed in the circular buffer 1002 in a clockwise direction. The circular buffer 1002 has size or circumference N₂ in this example. The circular buffer 1002 is read out in a counter-clockwise direction, starting from the N₂-th bit in the example shown, to obtain or provide code bits for transmission or output.

In the initial transmission or output RV0, M₀ code bits are transmitted or output, and the M₀ code bits are indexed by [N₂, N₂−1, N₂−2, . . . , N₂−M₀+1] in the maximum length mother code. In the second transmission or output RV1 (a first retransmission, incremental transmission, or incremental output), the next M₁ code bits are transmitted, and the M₁ code bits are indexed by [N₂−M₀, N₂−M₀−1, N₂−M₀−2 . . . . N₂−M₀−M₁+1] in the maximum length mother code. In a third transmission or output RV2 (a second retransmission, incremental transmission, or incremental output), the next M₂ code bits are transmitted, and the M₂ code bits are indexed by [N₂−M₀−M₁, N₂−M₀−M₁−1, N₂−M₀−M₁−2 . . . . N₂−M₀−M₁−M₂₊₁] in the maximum length mother code.

In this case, N₂>M₀+M₁+M₂, so there are P=N₂−M₀−M₁−M₂ untransmitted (or punctured) bits, but again puncturing is optional.

If more retransmissions, incremental transmissions, or incremental outputs are requested, then the P punctured bits may be transmitted or output in one or more additional retransmissions, incremental transmissions, or incremental outputs, until all code bits of the maximum length mother code bits are transmitted or output. Then, the previously transmitted or output code bits may be repeatedly transmitted or output, in counter-clockwise order in the example shown and as described above.

It should be noted that starting points, which may also or instead be referred to as starting positions, for transmission or output of RVs other than an initial transmission or output need not be pre-defined. The starting position for an RV subsequent to RV0, for example, might not be pre-defined, but be a next position immediately after the previous (immediately preceding) RV ended, or in other words the next position immediately after the ending position of the previous RV. Power of 2 starting points may be preferred in some embodiments, but in continuous transmission embodiments starting points need not be pre-defined.

It may, however, be useful to pre-define starting positions in order to simplify a coding description for a communication standard or specification for example, and/or potentially support self-decodability after a (re) transmission or incremental transmission or output. Two possibilities are considered as illustrative examples below, for a clockwise description and a counter-clockwise description related to circular buffer-based implementations. Note that the clockwise and counter-clockwise descriptions are equivalent if code bits are re-ordered into transmission or output order or into reverse-transmission or reverse-output order.

For a clockwise description, encoded bits may be reversed in order before writing into a circular buffer. With reference to FIG. 10 as an example, for reverse order writing to the circular buffer 1002 the encoded bit with index N₂ is placed in the first position (e.g., with index 1 in FIG. 10, but may be o in other embodiments) in the circular buffer.

For polar codes with maximum power of 2 mother code length N and four RVs of equal size as an example, there can be four power of 2 starting positions, which may be specified in a table such as Table 1 below for an example of positions in a circular buffer being indexed by o to N−1:

TABLE 1
Example Clockwise Circular Buffer Description
Clockwise Description

| rv_{id} | k₀ |
|---|---|
| 0 | 0 |
| 1 | N/4 |
| 2 | N/2 |
| 3 | N/4*3 |

Using this clockwise description example, code bit selection may be described in the form of pseudocode as outlined by way of example below. The bit sequence (optionally after optional interleaving by a rate matching interleaver for example) y₀, y₁, y₂, . . . , y_{N-1} is written into a circular buffer of length N. Here and elsewhere, references to transmission may be generalized to output rather than specifically transmission.

With E₀, E₁, E₂, E₃ denoting the number of transmitted or output bits in each redundancy version, in an embodiment:

```
If K/E₀ ≤ 7/16, puncturing is applied to initial transmission.
  All N bits in the circular buffer of length N can be transmitted.
Else if K/E₀ > 7/16, shortening is applied to both initial transmission and retransmissions.
  Only the N-P non-shortened bits in the circular buffer of length N can be
transmitted, and the shortened P bits will be skipped, where P= P₀+P₁+P₂+P₃ is the sum of
shortened bits in all four transmissions. Denote by S the set of shortened bit positions.
End if
```

Regarding the N bits in the circular buffer of length N being transmitted in the example above, and similarly in other examples below, this refers to the possibility of transmitting punctured code bits after all non-punctured code bits have already been transmitted but one or more further retransmissions, incremental transmissions, or incremental outputs are requested. Then the punctured code bits may be transmitted or output in one or more additional retransmissions, incremental transmissions, or incremental outputs, until all code bits for the maximum mother code length are transmitted or output. The punctured code bits may be transmitted or output according to a pre-defined order, such as an order determined by a puncturing order or pattern (such as the reverse of a puncturing sequence for example). In a circular buffer embodiment, another option is to transmit or output punctured code bits from the circular buffer in clockwise order (or counter-clockwise order), depending on how the code bits are placed into and/or read from the buffer.

Denoting by rvid the redundancy version number for this transmission (rvid=0, 1, 2 or 3), with ko given by Table 1 according to the value of ruid, and with E denoting the output sequence length (after optional rate matching), an output bit sequence ek, k=0, 1, 2, . . . , E−1, may be generated or otherwise obtained as follows:

```
k = 0;
while k < E
  if y_{mod(k0+k,N)} ∉ S
    eₖ = y_{mod(k0+k,N)};
    k=k+1;
  end if
end while
```

For a counter-clockwise description, for polar codes with maximum mother code length N and four RVs of equal size as an example, there can be four power of 2 starting positions, which may be specified in a table such as Table 2 below for an example of positions in a circular buffer being indexed by o to N−1:

TABLE 2
Example Counter-clockwise Circular Buffer Description
Counter-clockwise Description

| rv_{id} | k₀ |
|---|---|
| 0 | N − 1 |
| 1 | N/4*3 − 1 |
| 2 | N/2 − 1 |
| 3 | N/4 − 1 |

Using this counter-clockwise description example, code bit selection may be described in the form of pseudocode as outlined by way of example below.

```
If K/E₀ ≤ 7/16, puncturing is applied to initial transmission.
  All N bits in the circular buffer of length N can be transmitted.
Else if K/E₀ > 7/16, shortening is applied to both initial transmission and retransmissions.
  Only the N-P non-shortened bits in the circular buffer of length N can be
transmitted, and the shortened P bits will be skipped, where P= P₀+P₁+P₂+P₃ is the sum of
shortened bits in all four transmissions. Denote by S the set of shortened bit positions.
End if
```

With rvid denoting the redundancy version number for a transmission (rvid=0, 1, 2 or 3), ko given by Table 2 according to the value of rvid, and E denoting the output sequence length (after optional rate matching), a bit selection output bit sequence ek, k=0, 1, 2, . . . , E−1, may be generated or otherwise obtained as follows:

```
k = 0;
while k > −E
  if y_{mod(k0+k,N)} ∉ S
    eₖ = y_{mod(k0+k,N)};
    k=k−1;
  end if
end while
```

These examples are non-limiting. The number of redundancy versions can be other values, such as 2 instead 4, or more generally more or fewer than 4. An initial transmission code rate threshold to choose between puncturing and shortening can be different, such as 6/16 (or another value) instead of 7/16. These examples include the parameters of 5G NR for backward compatibility, but may be expressed differently in other embodiments. These generalizations may also or instead apply to other disclosed embodiments.

### Illustrative Embodiment 2−Circular Transmission or Output with Repetition

Circular transmission or output with repetition is also referred to herein as Embodiment 2.

Consider again the coding example provided above for Embodiment 1, with three segments and partial interleaving. In Embodiment 2, each segment is further divided or partitioned into D equal-sized blocks, with D=4 used below as an example.

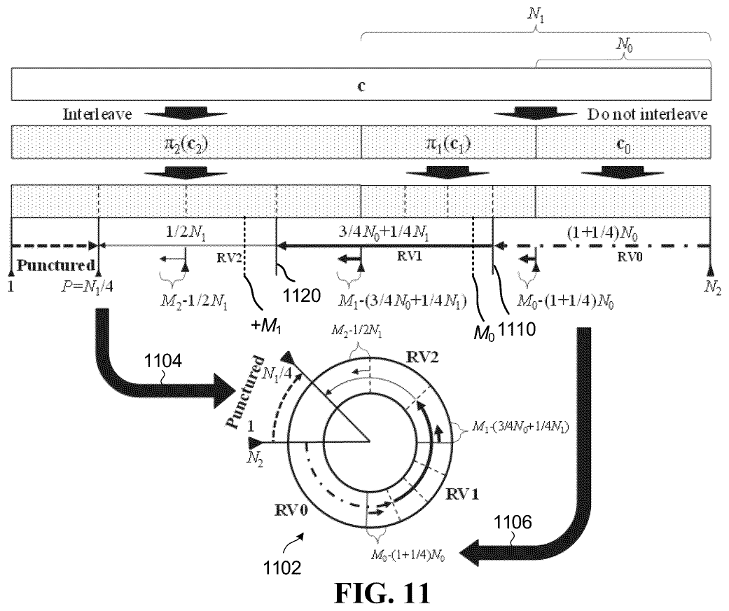

FIG. 11 is a diagram illustrating another embodiment that includes optional partial interleaving and puncturing. As in FIG. 10, FIG. 11 illustrates a codeword c of length N₂, which is divided or partitioned into three segments c₀ of length N₀=N₂/4, c₁ of length N₀=N₂/4, and c₂ of length N₁=N₂/2. Each of the segments c₂ and c₁, which are to be interleaved in the example shown, is further divided or partitioned into four blocks of equal size. Segments are delineated by solid vertical lines in the third row at the top of FIG. 11, and blocks within each segment are delineated by dashed vertical lines in that row. The blocks of any one segment are of equal size, but blocks that are in different segments may be of a different size. The number of blocks in each segment is the same for all of the segments that are further divided or partitioned into blocks in the example shown.

In other embodiments, all segments may be further divided or partitioned into blocks, the number of blocks per segment may or may not be the same for all segments, and/or block size may be the same for all segments. These are examples of features that may be different from the embodiment illustrated in FIG. 11.

As in FIG. 10, code bits of the partially interleaved maximum length mother codeword in FIG. 11 are placed in the circular buffer 1102 in a clockwise direction, as indicated by 1104, 1106. The circular buffer 1102 has size or circumference N₂ in this example, and is read out in a counter-clockwise direction, starting from the N₂-th bit in the example shown, to obtain or provide code bits for transmission or output.

In the initial transmission or output RV0, M₀ code bits are to be transmitted or output. However, the bit position N₂−M₀+1 (indicated by transmission or output length M₀ below the third row at the top of FIG. 11 to avoid further congestion) lies in the third block (relative to order of writing to the circular buffer 1102 or bit index order (or interleaved order if partially interleaved) of the second segment). According to Embodiment 2, transmission or output of code bits that have not previously been transmitted or output or otherwise included in another (re) transmission or output stops at the ending point of the previous (immediately preceding) block in the order of transmission, output, or reading from the circular buffer. This may be the reverse of writing order in which code bits are written to the circular buffer 1102, reverse bit index order in the case of no partial interleaving, or reverse interleaved order in the example shown. The previous block is the fourth block of the second segment. Transmission or output of code bits that have not been previously transmitted or otherwise included in another (re) transmission or output ends at the ending point or position of that block, and some code bits from the starting point of the fourth block of the second segment are repeated until M₀ bits have been transmitted or output. The number of repetition bits is M₀−(1+¼) N₀, such that the total number of transmitted code bits (including repetition bits) is M₀.

In the second transmission or output RV1 (a first retransmission, incremental transmission, or incremental output), M₁ code bits are to be transmitted or output, starting from the starting point 1110 of the third block of the second segment. However, the bit position N₂−(1+¼) N₀−M₁₊₁ (indicated by incremental transmission or output length “+M₁” below the third row at the top of FIG. 11 to avoid further congestion) lies in the third block of the first segment. According to Embodiment 2, transmission or output of new code bits stops at the ending point of the previous (immediately preceding block), which in this example is the fourth block of the first segment), and some of the code bits from the starting point in the fourth block of the first segment are repeated. The number of repetition bits is M₁−(¾N₀+¼N₁), such that the total number of transmitted or output code bits (including repetition bits) is M₁.

In the third transmission or output RV2 (a second retransmission, incremental transmission, or incremental output), M₂ code bits are to be transmitted or output, starting from the starting point 1120 of the third block of the first segment. However, the bit position N₂−(1+¼) N₁−M₂₊₁ lies in the first block of the first segment. According to Embodiment 2, transmission or output of new code bits stops at the ending point of the previous block, which is the second block of the first segment in this example, and some of the code bits from the starting point of the second block of the first segment are repeated. The number of repetition bits is M₂−½N₁, such that the total number of transmitted or output code bits (including repetition bits) is M₂.

In this example, N₂> (1+¾) N₁, so there are P=N₂−(1+¾) N₁=¼N₁ untransmitted (or punctured) code bits. As in Embodiment 1, if more retransmissions, incremental transmissions, or incremental outputs are requested, then the P punctured bits may be transmitted or output in one or more additional retransmissions, incremental transmissions, or incremental outputs, until all code bits of the maximum length mother code bits are transmitted or output. Then, the code bits that have been previously transmitted or output or otherwise included in another (re) transmission or output may be repeatedly transmitted or output, in counter-clockwise order in the example shown and as described above.

In Embodiment 2, the starting points and ending points for RVs are not entirely pre-defined, but depend on both power of 2 positions (where the blocks begin and end) and where a previous (re) transmission or output ends. Another difference from Embodiment 1 is that Embodiment 2 allows repetition.

Some embodiments may use pre-defined candidate starting positions and ending positions. Here, “candidate” is intended to indicate that there is freedom to select from these positions. Two possibilities are considered below, as for Embodiment 1 above: for a clockwise description and a counter-clockwise description. As above, the clockwise and counter-clockwise descriptions are equivalent if code bits are re-ordered into transmission or output order or into reverse-transmission or reverse-output order.

For a clockwise description, encoded bits may be reversed in order before writing into a circular buffer. With reference to FIG. 11 as an example, for reverse order writing to the circular buffer 1102 the encoded bit with index N₂ is placed in the first position (e.g., with index 1 in FIG. 11, but may be o in other embodiments) in the circular buffer.

For polar codes with maximum power of 2 mother code length N, and with segmentation and blocks as shown in FIG. 11, candidate starting positions and ending positions may be specified in a table such as Table 3 below for an example of positions in a circular buffer being indexed by o to N−1:

TABLE 3
Example Clockwise Circular Buffer Description with Blocks
Clockwise Description

| Position index | k₀ |
|---|---|
| 0 | 0 |
| 1 | N/4 |
| 2 | 5N/16 = N/4 + N/16 |
| 3 | 3N/8 = N/4 + N/16*2 |
| 4 | 7N/16 = N/4 + N/16*3 |
| 5 | N/2 |
| 6 | 5N/8 = N/2 + N/8 |
| 7 | 3N/4 = N/2 + N/8*2 |
| 8 | 7N/8 = N/2 + N/8*3 |

As shown, these are positions with power of 2 spacings, and some with power of 2 values. These positions are denoted by a starting/ending position set PS for ease of reference.

Using this clockwise description example, code bit selection may be described in the form of pseudocode as outlined by way of example below, using notation as introduced above.

```
  If K/E₀ ≤ 7/16, puncturing is applied to initial transmission.
    All N bits in the circular buffer of length N can be transmitted.
  Else if K/E₀ > 7/16, shortening is applied to both initial transmission and retransmissions.
    Only the N-P non-shortened bits in the circular buffer of length N can be
  transmitted, and the shortened P bits will be skipped, where P= P₀+P₁+P₂+P₃ is the sum of
  shortened bits in all four transmissions.
  End if
```

In this embodiment, the starting/ending positions are not tied to the redundancy version number (rv_{id}=0, 1, 2 or 3). The starting position ko is chosen from the above candidate positions, depending on the transmission of the previous redundancy version (specifically, its ending position v₀).

The initial values of starting position ko and ending position v₀ are:

$${k}_{o} = o ;$$

$${υ}_{o} = o ;$$

and for a new redundancy version (e.g., retransmission), the starting position is the ending position of the previous redundancy version:

$${k}_{o} = {υ}_{o} .$$

Given a starting position k₀, and output sequence (optionally from rate matching) length E, the ending position v₀ is calculated by:

$${υ}_{o} = argmax \{ {υ}_{o} : {υ}_{o} \leq {k}_{o} + E , {υ}_{o} ∈ P S \}$$

or in other words, the ending position v₀ is the largest number in the position set PS which is no larger than k₀+E.

A repetition starting position k₁ for possible repetition may be defined as follows:

$${k}_{1} = argmax \{ {k}_{1} : {k}_{1} < {υ}_{0} , {k}_{1} ∈ P S \}$$

or in other words, the repetition starting position k₁ is the largest number in the position set PS which is smaller than vo.

An output bit sequence eₖ, k=0, 1, 2, . . . , E−1, may be generated or otherwise obtained as follows:

```
k = 0;
while k < v₀−k₀
  if y_{mod(k0+k,N)} ∉ S
    eₖ = y_{mod(k0+k,N)};
    k=k+1;
  end if
end while
while k < E
  if y_{mod(k1+k0-v0+k,N)} ∉ S
    eₖ = y_{mod(k1+k0-v0+k,N)};
    k=k+1;
  end if
end while
```

In the above example, “while k<v₀−k₀” relates to continuous transmission, and “while k<E” relates to repetition.

The example pseudocodes herein, including the above example and others, may have other equivalent descriptions.

For a counter-clockwise description, for polar codes with maximum mother code length N, and with segmentation and blocks as shown in FIG. 11, candidate starting positions and ending positions may be specified in a table such as Table 4 below for an example of positions in a circular buffer being indexed by o to N−1:

TABLE 4
Example Counter-clockwise Circular Buffer Description with Blocks
Counter-clockwise Description

| Position index | k₀ |
|---|---|
| 0 | N − 1 |
| 1 | 3N/4 − 1 |
| 2 | 11N/16 − 1 = |
| | 3N/4 − N/16 − 1 |
| 3 | 5N/8 − 1 = |
| | 3N/4 − N/16*2 − 1 |
| 4 | 9N/16 − 1 = |
| | 3N/4 − N/16*3 − 1 |
| 5 | N/2 − 1 |
| 6 | 3N/8 − 1 = N/2 − N/8 − 1 |
| 7 | N/4 − 1 = N/2 − N/8*2 − 1 |
| 8 | N/8 − 1 = N/2 − N/8*3 − 1 |

Using this counter-clockwise description example, code bit selection may be described in the form of pseudocode as outlined by way of example below, using notation as introduced above.

```
If K/E₀ ≤ 7/16, puncturing is applied to initial transmission.
  All N bits in the circular buffer of length N can be transmitted.
Else if K/E₀ > 7/16, shortening is applied to both initial transmission and retransmissions.
  Only the N-P non-shortened bits in the circular buffer of length N can be
transmitted, and the shortened P bits will be skipped, where P= P₀+P₁+P₂+P₃ is the sum of
shortened bits in all four transmissions.
End if
```

In this example, the starting/ending positions are again not tied to the redundancy version number (rv_{id}=0, 1, 2 or 3). The starting position k₀ is chosen from the above candidate positions, depending on the transmission of the previous redundancy version (specifically, its ending position v₀).

The initial values of starting position ko and ending position v₀ are:

$${k}_{o} = N - 1 ;$$

$${υ}_{o} = N - 1 ;$$

and for a new redundancy version (e.g., retransmission), the starting position is the ending position of the previous redundancy version:

$${k}_{o} = {υ}_{o} .$$

Given a starting position k₀, and output sequence (optionally from rate matching) length E, the ending position v₀ is calculated by:

$${υ}_{o} = argmin \{ {υ}_{o} : {υ}_{o} \geq {k}_{o} - E , {υ}_{o} ∈ P S \}$$

or in other words, the ending position v₀ is the smallest number in the position set PS which is no smaller than k₀+E.

A repetition starting position k, for possible repetition may be defined as follows:

$${k}_{1} = argmin \{ {k}_{1} : {k}_{1} > {υ}_{o} , {k}_{1} ∈ P S \}$$

or in other words, the repetition starting position k, is the smallest number in the position set PS which is larger than vo.

An output bit sequence eₖ, k=0, 1, 2, . . . , E−1, may be generated or otherwise obtained as follows:

```
k = 0;
while k > −(v₀−k₀)
  if y_{mod(k0+k,N)} ∉ S
    eₖ = y_{mod(k0+k,N)};
    k=k−1;
  end if
end while
while k > −E --- repetition
  if y_{mod(k1-(k0-v0)+k,N)} ∉ S
    eₖ = y_{mod(k1-(k0-v0)+k,N)};
    k=k−1;
  end if
end while
```

In the above example, “while k>−(v₀−k₀)” relates to continuous transmission, and “while k>−E” relates to repetition.

### Illustrative Embodiment 3—Circular Transmission or Output with Conditional Repetition

Embodiment 3 is used herein to refer to circular transmission or output with conditional repetition.

As for Embodiment 2 above, consider a coding example with three segments and partial interleaving, and in which segments are further divided or partitioned into D equal-sized blocks, with D=4 used below as an example.

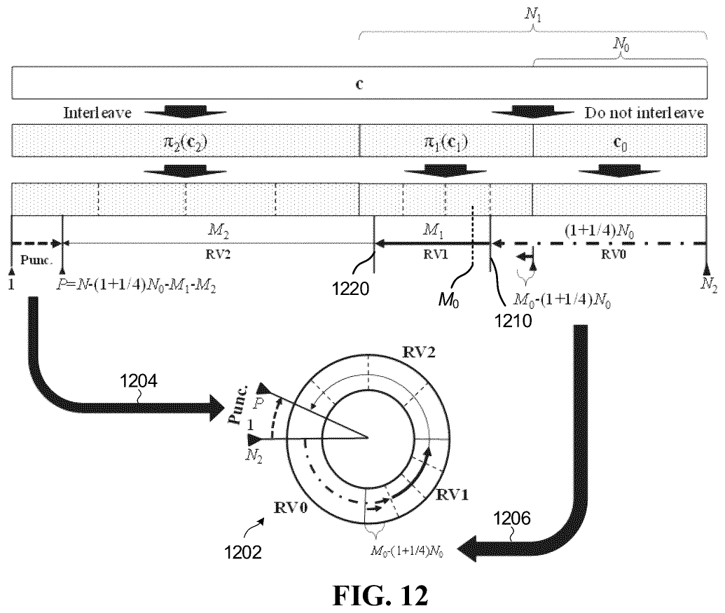

FIG. 12 is a diagram illustrating a further embodiment that includes optional partial interleaving and puncturing, and shows a codeword c of length N₂, which is divided or partitioned into three segments c₀ of length N₀=N₂/4, c₁ of length N₀=N₂/4, and c₂ of length N₁=N₂/2. Each of the segments c₂ and c₁, which are to be interleaved in the example shown, is further divided or partitioned into four blocks of equal size. As in FIG. 11, segments are delineated by solid vertical lines in the third row at the top of FIG. 12, and blocks within each segment are delineated by dashed vertical lines in that row. Segments and blocks may be different than shown, in other embodiments.

As in FIG. 11, code bits of the partially interleaved maximum length mother codeword in FIG. 12 are placed in the circular buffer 1202 in a clockwise direction, as indicated by 1204, 1206. The circular buffer 1202 has size or circumference N₂ in this example, and is read out in a counter-clockwise direction, starting from the N₂-th bit in the example shown, to obtain or provide code bits for transmission or output.

In the initial transmission or output RV0, M₀ code bits are to be transmitted or output. However, the bit position N₂−M₀+1 (indicated by transmission or output length M₀ below the third row at the top of FIG. 12 to avoid further congestion) lies in the third block (relative to order of writing to the circular buffer 1202 or bit index order (or interleaved order if partially interleaved) of the second segment). In Embodiment 3, continuous transmission or repetition may be used for each RV.

As an example, based on the RV index i=0 of the current RV0 being smaller than a threshold, i.e., i<1(iₜₕ=1), AND d mod D₀=D₀−1 (d=3, D₀=4), then select or adopt transmission with repetition, consistent with Embodiment 2. According to Embodiment 2, transmission or output of code bits that have not previously been transmitted or output or otherwise included in another (re) transmission or output stops at the ending point of the previous (immediately preceding) block in the order of transmission, output, or reading from the circular buffer. This may be the reverse of writing order in which code bits are written to the circular buffer 1202, reverse bit index order in the case of no partial interleaving, or reverse interleaved order in the example shown. The previous block is the fourth block of the second segment. Transmission or output of code bits that have not been previously transmitted or otherwise included in another (re) transmission or output ends at the ending point or position of that block, and some code bits from the starting point of the fourth block of the second segment are repeated until M₀ bits have been transmitted or output. The number of repetition bits is M₀−(1+¼) N₀, such that the total number of transmitted code bits (including repetition bits) is M₀.

In the second transmission or output RV1 (a first retransmission, incremental transmission, or incremental output), M₁ code bits are to be transmitted or output, starting from the starting point 1210 of the third block of the second segment. Again, a selection may be made between continuous transmission and repetition. For example, based on the RV index i=1 of the current RV1 not being smaller than a threshold, i.e., i=1 (iₜₕ=1), select or adopt continuous transmission according to Embodiment 1. The next M₁ code bits in the maximum length mother code are transmitted, specifically bits indexed by [N₂−(1+¼) N₀, N₂−(1+¼) N₀−1, N₂−(1+¼) N₀−2 . . . . N₂−(1+¼) N₀−M₁₊₁] in this example, even though the ending point for RV1 falls within the first block of the second segment as shown at 1220.

In the third transmission or output RV2 (a second retransmission, incremental transmission, or incremental output), M₂ code bits are to be transmitted or output, starting with the N₂−(1+¼) N₀−M₁-th bit, after 1220. Based on an RV index criterion or condition, with i=2 of the current RV2 not being smaller than a threshold, i.e., i>1 (iₜₕ=1), continuous transmission according to Embodiment 1 is selected or adopted. The next M₂ code bits in the maximum length mother code are transmitted, specifically bits indexed by [N₂−(1+¼) N₀−M₁, N₂−(1+¼) N₀−M₁−1, N₂−(1+¼) N₀−M₁−2 . . . . N₂−(1+¼) N₀−M₁−M₂₊₁] in this example.

In this example, N₂> (1+¼) N₀+M₁+M₂, so there are P=N₂−(1+¼) N₀−M₁-M₂ untransmitted (or punctured) bits. As in Embodiments 1 and 2, if more retransmissions, incremental transmissions, or incremental outputs are requested, then the P punctured bits may be transmitted or output in one or more additional retransmissions, incremental transmissions, or incremental outputs, until all code bits of the maximum length mother code bits are transmitted or output. Then, the previously transmitted or output code bits may be repeatedly transmitted or output, in counter-clockwise order in the example shown and as described above.

Pseudocodes to describe Embodiment 3 may be substantially the same as for Embodiment 2, except that the selections of starting and ending points are additionally based on selection conditions such as RV index in the above example, or other conditions that are provided by way of example elsewhere herein. That is, starting points and/or ending points can be either selected from a starting/ending position set PS, or continue from the previous ending/starting positions.

Specifically, if a repetition condition is satisfied (e.g., overall code rate before this retransmission is higher than a pre-defined threshold code rate Rₜₕ), then select a starting position and an ending position as in Embodiment 2; and otherwise, if the repetition condition is not satisfied (e.g., overall code rate before this retransmission is smaller than a pre-defined threshold code rate Rₜₕ), then continue to transmit or output code bits for an RV according to Embodiment 1.

Equivalently, conditional repetition in Embodiment 3 may be described as follows: if a continuous transmission condition is not satisfied (e.g., overall code rate before this retransmission is smaller than a pre-defined threshold code rate Rₜₕ), then continue to transmit or output code bits for an RV according to Embodiment 1; and otherwise, if the continuous repetition condition is not satisfied (e.g., overall code rate before this retransmission is higher than a pre-defined threshold code rate Rₜₕ), then select a starting position and an ending position as in Embodiment 2.

### OVERVIEW

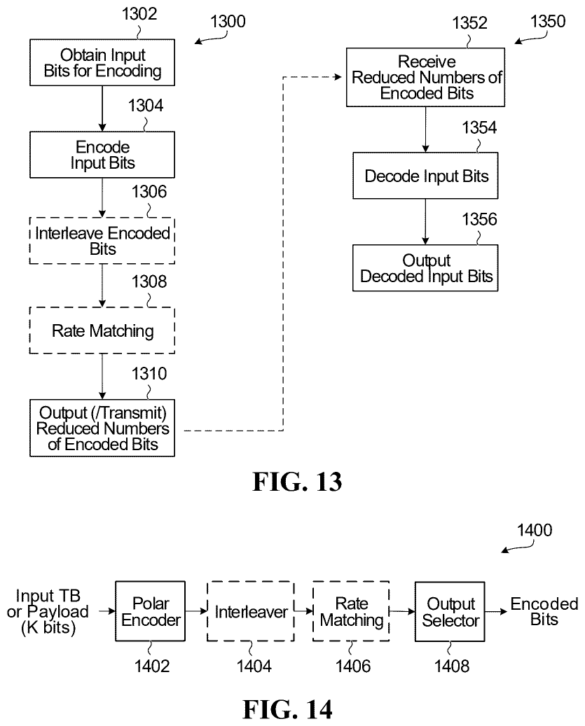

Various aspects of the present disclosure are described herein and shown in the drawings by way of example. FIG. 13 is a flow diagram illustrating general example methods according to embodiments. At the left, 1300 in FIG. 13 illustrates operations or features that may be provided or supported at an encoder or transmitter-side device, and at the right, 1350 illustrates operations or features that may be provided or supported at a decoder or receiver-side device. For ease of reference, in the following description of FIG. 13, a device at which encoding and/or transmitting features may be implemented or supported is called a first communication device, and a device at which decoding and/or receiving features may be implemented or supported is called a second communication device. Embodiments may involve either or both of such devices.

With reference first to 1300, from a transmitting device perspective the outputting of encoded bits at 1310 may involve transmitting the encoded bits. Encoded bits may be output through or via any of various types of interface, including a communication interface in the case of transmitting the encoded bits. Embodiments are not in any way restricted to any particular type of interface. Encoded bits may be transmitted at 1310 by a first communication device to a second communication device in a wireless communication network, for example.

The encoded bits are obtained by encoding input bits by a polar code at 1304, and may be referred to as encoded bits encoded by the polar code. Encoding at 1304 may be implemented or performed by an encoder or a processor, for example, and outputting encoded bits at 1310 need not necessarily involve transmission of encoded bits. Encoded bits may be output at 1310 for storage to memory for example, and/or transmission.

A polar code comprises or provides bit indices for placing bit values before encoding. The bit indices include a first set of bit indices for placing values of input bits, and a second set of bit indices for placing a predetermined bit value. An information set including bit indices for placement of input bit values is an example of the first set, and a frozen set including bit indices for placement of a predetermined frozen bit value is an example of the second set.

Not all of the encoded bits obtained by the encoding at 1304 are output at the same time at 1310. IR-HARQ is an example of an application in which code bits are incrementally transmitted, and more generally the outputting at 1310 involves outputting fewer than all of the encoded bits in incremental outputs. For example, outputting at 1310 may involve outputting a first reduced number of the encoded bits starting from a first starting position, and outputting a second reduced number of the encoded bits that include one or more of the encoded bits not included in the first reduced number of the encoded bits and start from a second starting position different from the first starting position. Although this example refers to first and second reduced numbers of encoded bits, there may be more than one retransmission or output after an initial transmission or output of code bits. Embodiments herein are not limited to any particular number of transmissions or outputs.

Thus, there is more than one output of encoded bits at 1310. In some embodiments, the outputting at 1310 may involve outputting different numbers of encoded bits in multiple outputs. With reference to the first reduced number and the second reduced number of encoded bits in an example above, the first reduced number and the second reduced number, for any two transmissions or outputs, may be the same or different.

Consider an embodiment that involves transmitting encoded bits from a first communication device to a second communication device in a wireless communication network, for example. Outputting at 1310 may involve such transmitting in some embodiments, or outputting and transmitting features may be implemented separately, by an encoder and a transmitter for example. A method may involve (or further include, in addition to outputting) transmitting the first reduced number of encoded bits, and transmitting, in an incremental transmission, a second reduced number of the encoded bits including one or more additional encoded bits. This second reduced number of the encoded bits include one or more of the encoded bits not included in the first reduced number of the encoded bits. There may be more than one incremental transmission (or output) of the same number or different numbers of additional encoded bits. An incremental transmission or output, such as the above-referenced second reduced number of encoded bits, includes one or more encoded bits that were not previously transmitted or output or otherwise included in another (re) transmission or output, in the above-referenced first reduced number of encoded bits for example, but may also include bits from another (re) transmission or output as well. According to an IR-HARQ approach, if the transmitted bits are not successfully decoded, then one or more additional encoded bits may be transmitted, in each of one or more incremental transmissions.

Some embodiments herein involve partial interleaving, and the interleaving at 1306 in FIG. 13 involves interleaving a subset of the encoded bits obtained at 1304. In some embodiments, a subset of the encoded bits for interleaving includes a power of 2 number of the encoded bits, which may be particular preferred for power of 2 length mother polar codes.

The subset of encoded bits that is interleaved at 1306 includes fewer than all of the encoded bits, as illustrated by way of example in FIGS. 10 to 12 for multiple separately interleaved subsets, which are also referred to herein as segments. The examples in FIGS. 10 to 12 include multiple subsets or segments, but more generally one or more subsets or segments of encoded bits may be interleaved, to obtain partially interleaved encoded bits. In embodiments that involve partial interleaving, the reduced numbers of encoded bits that are output at 1310 include partially interleaved encoded bits. With reference again to first and second reduced numbers of encoded bits in an example above, the first reduced number of the encoded bits may include the first reduced number of partially interleaved encoded bits, and the second reduced number of the encoded bits may include the second reduced number of the partially interleaved encoded bits. More generally, an incremental transmission or output, such as an RV, may include a reduced number of partially interleaved encoded bits that are obtained by partially interleaving encoded bits.

To be clear, partially interleaved encoded bits include encoded bits that have been interleaved and encoded bits that have not been interleaved. The second row in each of FIGS. 10 to 12 provides an example. In each of these drawings, the encoded bits in the second row are partially interleaved encoded bits. The c₀ encoded bits are not interleaved, and the c₁ and c₂ encoded bits are interleaved. Together, the ₂c₂ interleaved encoded bits, the π₁c₁ interleaved encoded bits, and the c₀ (non-interleaved) encoded bits are partially interleaved encoded bits, and the RVs include respective reduced numbers of the partially interleaved encoded bits.

Rate matching, by puncturing and/or shortening for example, may be provided or supported in some embodiments, and is shown at 1308. Rate matching at 1308 may be preferably restricted to encoded bits that are interleaved at 1306.

Another operation that may be involved in a method according to some embodiments is illustrated at 1302. Obtaining input bits for encoding may involve, for example, collecting or otherwise receiving data outputs from one or more devices and/or services, or accessing data in a memory.

Embodiments may include any or all of the operations illustrated at 1300. For example, in some embodiments, a method may involve encoding as shown at 1304 and transmitting or otherwise outputting encoded bits at 1310. Other embodiments may involve transmitting or otherwise outputting, at 1310, encoded bits that have already been obtained by encoding input bits by a polar code. Some embodiments may involve partial interleaving at 1306 and rate matching at 1308. The features shown at 1300 in FIG. 13 are not mutually exclusive, and methods may involve the obtaining at 1302, the encoding at 1304, the partial interleaving at 1306, the rate matching at 1308, and also the outputting at 1310.

Features may be implemented in any of various ways, and/or other features may also or instead be provided or supported.

For example, Embodiment 1, Embodiment 2, and Embodiment 3 herein relate primarily to management of encoded bits for output at 1310.

Consistent with Embodiment 1, the above-referenced first reduced number of the encoded bits may include encoded bits starting from the first starting position and ending at a first ending position, and the second starting position (of the above-referenced second reduced number of encoded bits) immediately follows the first ending position. More generally, a transmission or output of a number of encoded bits, such as an RV, may start at a next bit after the last bit of a preceding transmission or output (such as a preceding RV), or in other words start at a starting position that immediately follows the ending position of the preceding transmission or output (such as a preceding RV).

An incremental transmission or output such as an RV may include a power of 2 number of encoded bits. Considering again the above-referenced first and second reduced numbers of encoded bits, the first reduced number of the encoded bits may include a power of 2 number of the encoded bits starting from the first starting position and ending at the first ending position, and the second reduced number of the encoded bits may include a power of 2 number of the encoded bits starting from the second starting position and ending at a second ending position. As noted elsewhere herein, power of 2 numbers of encoded bits may be preferred for polar codes.

Other features disclosed herein, including but not limited to those disclosed in the context of Embodiment 1, may also or instead be provided or supported for incremental transmissions or outputs such as the above-referenced first and second reduced numbers of encoded bits.

Regarding Embodiment 2, as an example in the context of the first and second reduced number of encoded bits referenced above, the first reduced number of the encoded bits may include encoded bits starting from the first starting position and ending at the first ending position, the second starting position may immediately follow the first ending position, and the second reduced number of the encoded bits may include encoded bits starting from the second starting position and ending at the second ending position. However, there may be one or more repeated bits, as illustrated by way of example below the third row at the top of FIG. 11. Considering RV0 in FIG. 11, RV0 includes encoded bits from its starting position N₂ to its (reset) ending position 1110, and there are M₀−(1+¼) N₀ repeated encoded bits. The repeated encoded bits are encoded bits that are between the starting position and the ending position of RV0. Similarly, RV1 and RV2 also include repeated encoded bits. For the above-referenced example, the first reduced number of the encoded bits may include one or more repeated first encoded bits and/or the second reduced number of the encoded bits may include one or more second repeated encoded bits.

As discussed in further detail elsewhere herein, ending positions may be reset based on current transmission or output length (e.g., RV length or Mᵢ) and block starting and ending positions. For example, the above-referenced first ending position may be an ending position of a first one of a plurality of power of 2 length blocks of the encoded bits, and the first reduced number of the encoded bits may include one or more repeated first encoded bits where there are fewer than the first reduced number of the encoded bits between the first starting position and the first ending position. With reference to FIG. 11 as an example, the length of RV0 is M₀, but continuous transmission or output would result in RV0 ending at a position within a block instead of at a block ending position. Consistent with Embodiment 2, the ending positions of RV2 is reset to the ending position of the preceding block, at 1110. There are new fewer than M₀ encoded bits between the starting position and the ending position of RV0, and accordingly RV0 includes repeated encoded bits.

Similarly, for the above-referenced second reduced number of the encoded bits, the second ending position may be an ending position of a second one of the power of 2 length blocks of the encoded bits, and the second reduced number of the encoded bits may include one or more repeated second encoded bits where there are fewer than the second reduced number of the encoded bits between the second starting position and the second ending position.

More generally, based on incremental transmission or output length and blocks of encoded bits, an incremental transmission or output may include one or more repeated encoded bits. This may be implemented, for example, by stopping the transmitting or outputting of new code bits that have not previously been transmitted or output or otherwise included in another (re) transmission or output, and instead repeating one or more encoded bits that have already been transmitted or output or otherwise included in another (re) transmission or output.

Although blocks may be implemented in combination with segments, with segments being further divided or partitioned into blocks, it should be appreciated that blocks may be implemented independently of segments.

Repeated encoded bits may be associated with a repetition starting point, shown by way of example as starting positions for repeated encoded bits below the third row at the top of FIG. 11. Continuing with an example above, the one or more repeated first encoded bits included in the first reduced number of encoded bits may include one or more of the encoded bits starting from a first repetition starting position and ending at the first ending position, and the first repetition starting position is based on the first reduced number of the encoded bits and the first ending position. With reference to FIG. 11 and using RV0 as an example, the repetition starting position is based on the reduced number of encoded bits (M₀) and the ending position of RV0, which is (1+¼)N₀, and the repeated encoded bits include encoded bits starting from the repetition starting position and ending at the ending position 1110. Note that not all of the encoded bits starting from the repetition starting position and ending at the ending position 1110 are repeated, but the repeated bits include one or more of these encoded bits.

In the example above related to a second reduced number of encoded bits, similarly the one or more repeated second encoded bits may include one or more of the encoded bits (which may include all of those encoded bits or only some of those encoded bits) starting from a second repetition starting position and ending at the second ending position, and the second repetition starting position may be based on the second reduced number of the encoded bits and the second ending position. See RV2 in FIG. 11 as an example, with a starting position immediately after 1110, a reduced number of bits M₁, and an ending position 1120. RV3 in FIG. 11 is another example, with a starting position immediately after 1120, a reduced number of bits M₂, and an ending position P+1.

Other features disclosed herein, including but not limited to those disclosed in the context of Embodiment 2, may also or instead be provided or supported for incremental transmissions or outputs such as the above-referenced first and second reduced numbers of encoded bits.

Embodiment 3 may provide or support features from both Embodiment 1 and Embodiment 2, and selection between such features. This is also referred to herein as transmission or output with conditional repetition. In the context of an example above, consistent with Embodiment 3, outputting the first reduced number of encoded bits starting from the first starting position may involve selecting between outputting the first reduced number of the encoded bits starting from the first starting position and ending at a first ending position with or without one or more repeated first encoded bits, or in other words selecting between outputting the first reduced number of bits including or not including one or more repeated first encoded bits. Outputting the second reduced number of the encoded bits starting from the second starting position may also or instead involve selecting between outputting the second reduced number of the encoded bits starting from the second starting position immediately following the first ending position and ending at a second ending position with or without one or more repeated second encoded bits, or in other words selecting between outputting the second reduced number of bits including or not including one or more repeated second encoded bits.

The selecting, for outputting the first reduced number of the encoded bits and/or for outputting the second reduced number of the encoded bits, or more generally for outputting a reduced number of encoded bits for an incremental transmission or output such as an RV, may involve selecting based on any one or more of the following:
preceding code rate of a preceding reduced number the encoded bits—an example is provided at least above, with reference to code rate before, or preceding code rate;
subsequent code rate of a subsequent reduced number the encoded bits—an example is provided at least above, with reference to code rate after, or subsequent code rate;
a redundancy version index associated with the outputting-examples are provided at least above, with reference to RV index and RV number or order;
position of a block of a plurality of blocks of the encoded bits-examples are provided at least above, with reference to block position in a segment and block index d.

Conditions or bases for selecting may be combined, and any of these examples may be combined with one or more others. Examples of combined conditions provided above include selecting based on combined code rate (before or after) and block index d, and selecting based on RV index and block index d.

Other features disclosed herein, including but not limited to those disclosed in the context of Embodiment 3, may also or instead be provided or supported for incremental transmissions or outputs such as the above-referenced first and second reduced numbers of encoded bits.

Further variations are also possible. For example, in embodiments that involve segmentation, segment size can become larger, or segmentation might not be applied at all, as more encoded bits are transmitted or output. FIGS. 11 and 12 show examples in which transmission or output is from left to right in the third row at the top, and counter-clockwise at the bottom. In both of these examples, segment size for c₁, which is transmitted or output earlier than c₂, is smaller than segment size for c₂, or in other words as more encoded bits are transmitted or output or for encoded bits that are later in a transmission or output order (in this example after the encoded bits in c have been transmitted or output or are to be transmitted or output), segment size is larger. Put another way, segment size may increase with transmission or output order or index, such that encoded bits that are transmitted later or have a higher index in respect of order of transmission may be from a segment with larger segment size than encoded bits that are transmitted earlier or have a lower index in respect of order of transmission.

Another possible variation relates to segmentation after all encoded bits have been transmitted or output, following a complete cycle of an initial transmission and retransmissions. For example, after all code bits for maximum mother code length have been transmitted or output, further retransmissions (in a second or subsequent “loop” or cycle) are repetition only because all encoded bits have already been transmitted or output, and therefore power-of-2 segmentation of encoded bits might not be used.

At 1350, FIG. 13 illustrates various decoding and/or receiving counterparts of features shown at 1300. From a receiving device perspective, the receiving at 1352 represents a first reduced number and a second reduced number of encoded bits that have been encoded by a polar code. The receiving at 1352 may involve receiving the first reduced number of the encoded bits from a first communication device by a second communication device in a wireless communication network and receiving, in an incremental transmission from the first communication device by the second communication device, the second reduced number of the encoded bits, for example. Encoded bits may be received through or via any of various types of interface, and embodiments are not in any way restricted to any particular type of interface.

The polar code, as in other embodiments herein, includes a number of bit indices for placing bit values before encoding, and the bit indices include a first set of bit indices for placing values of the input bits and a second set of bit indices for placing a predetermined bit value. The second reduced number of the encoded bits include one or more of the encoded bits not included in the first reduced number of the encoded bits and starting from a second starting position different from a first starting position of the first reduced number of the encoded bits.

The decoding at 1354 is intended to illustrate decoding the received first reduced number of encoded bits and second reduced number of encoded bits to obtain decoded input bits. Decoding at 1354 may be implemented or performed by a decoder or a processor, for example.

In some embodiments, a decoder might not be a discrete device, but rather a block of logic in silicon or part of a system-on-chip that decodes and uses the decoded input bits. In other embodiments, the decoded input bits are output as shown at 1356, for processing and/or storage, for example.

Any or all of the features that are described herein in the context of encoder-side or transmitter-side methods, with reference to operations at 1300 in FIG. 13, for example, may also apply to or have counterpart features in a decoder-side or receiver-side method. Any one or more of the following features, for example, may be provided or supported, individually or in any of various combinations, in a decoder-side or receiver-side method:
a subset of the encoded bits that includes fewer than all of the encoded bits may have been interleaved to obtain partially interleaved encoded bits;
the first reduced number of the encoded bits includes the first reduced number of the partially interleaved encoded bits;
the second reduced number of the encoded bits includes the second reduced number of the partially interleaved encoded bits;
the subset of the encoded bits includes a power of 2 number of the encoded bits;
the first reduced number of the encoded bits includes encoded bits starting from the first starting position and ending at a first ending position and the second starting position immediately follows the first ending position;
the first reduced number of the encoded bits includes a power of 2 number of the encoded bits starting from the first starting position and ending at the first ending position;
the second reduced number of the encoded bits includes a power of 2 number of the encoded bits starting from the second starting position and ending at a second ending position;
the first reduced number of the encoded bits includes encoded bits starting from the first starting position and ending at a first ending position, the second starting position immediately follows the first ending position and the second reduced number of the encoded bits includes encoded bits starting from the second starting position and ending at a second ending position, the first reduced number of the encoded bits incudes one or more repeated first encoded bits and/or the second reduced number of the encoded bits includes one or more second repeated encoded bits;
the first ending position is an ending position of a first one of a plurality of power of 2 length blocks of the encoded bits;
the first reduced number of the encoded bits includes the one or more repeated first encoded bits where there are fewer than the first reduced number of the encoded bits between the first starting position and the first ending position;
the second ending position is an ending position of a second one of the plurality of power of 2 length blocks of the encoded bits;
the second reduced number of the encoded bits includes the one or more repeated second encoded bits where there are fewer than the second reduced number of the encoded bits between the second starting position and the second ending position;
the one or more repeated first encoded bits includes one or more of the encoded bits starting from a first repetition starting position and ending at the first ending position;
the first repetition starting position is based on the first reduced number of the encoded bits and the first ending position;
the one or more repeated second encoded bits includes one or more of the encoded bits starting from a second repetition starting position and ending at the second ending position;
the second repetition starting position is based on the second reduced number of the encoded bits and the second ending position;
the first reduced number of the encoded bits may have been selected for transmission starting from the first starting position and ending at a first ending position with or without one or more repeated first encoded bits;
the second reduced number of the encoded bits may have been selected for transmission starting from the second starting position immediately following the first ending position and ending at a second ending position with or without one or more repeated second encoded bits;
the selection for transmission with or without the one or more repeated first or second encoded bits may have been based on any one or more of: preceding code rate of a preceding reduced number the encoded bits; subsequent code rate of a subsequent reduced number the encoded bits; a redundancy version associated with the outputting; and position of a block of a plurality of blocks of the encoded bits.

Embodiments may involve other features or operations as well. For example, some embodiments may involve communicating signaling that is indicative of any of various parameters, such as any one or more of: cyclic buffer design, starting points or positions of RVs, a maximum number of polar transformation matrix extensions, etc. Communicating of signaling may involve transmitting the signaling by an encoder/encoding device or a transmitter/transmitting device that is to transmit encoded bits, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which encoded bits are to be transmitted or received. For example, a network device such as a gNB or a base station may transmit signaling to configure parameters at one or more communication devices. Therefore, a method may involve a network device transmitting signaling, and an encoder/encoding device or a transmitter/transmitting device receiving the signaling from the network device, and/or a decoder/decoding device or a receiver/receiving device receiving the signaling from the network device.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor that is configured, by executing programming for example, to cause the apparatus to perform a method or operations, or to provide or support features, disclosed herein. An apparatus may also include a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to, or a processor, device, or other component may otherwise be configured to, encode a number of input bits by a polar code to obtain encoded bits, with the polar code comprising a number of bit indices for placing bit values before encoding. The bit indices include a first set of bit indices for placing values of the input bits and a second set of bit indices for placing a predetermined bit value.

Programming may also include instructions to or to cause a processor to, or a processor, device, or other component may otherwise be configured to, output a first reduced number of the encoded bits starting from a first starting position, and output a second reduced number of the encoded bits, with the second reduced number of the encoded bits including one or more of the encoded bits not included in the first reduced number of the encoded bits and starting from a second starting position different from the first starting position.

Apparatus embodiments are not limited to the foregoing examples, or to processor-based or programming-based embodiments. An apparatus may also or instead include, for example, an encoder for encoding the input bits by the polar code, and an interface coupled to the encoder for outputting the first reduced number of the encoded bits and outputting the second reduced number of the encoded bits. Encoded bits may be output via any of various types of interface, including a communication interface in the case of transmitting the encoded bits. Embodiments are not in any way restricted to any particular type of interface, the implementation of which may be based at least in part on how encoded bits are to be output.

FIG. 14 is a block diagram illustrating an apparatus in which embodiments may be implemented or supported. The example apparatus 1400 includes a polar encoder 1402, an optional interleaver 1404 coupled to the polar encoder, an optional rate matching module 1406 coupled to the interleaver, and an output selector 1408. Input bits for encoding are shown as input TB or payload bits, and encoded bits are shown as an output of the output selector 1408. An interface for transmitting or otherwise outputting the first reduced number of encoded bits and the second reduced number of encoded bits may be provided by, incorporated into, or coupled to, any one or more of the polar encoder 1402, the interleaver 1404, the rate matching module 1406, and the output selector 1408.

Encode-side or transmit-side features or functions, and other features or functions herein, may be implemented in any of various ways, such as in hardware, firmware, or one or more components that execute software. The present disclosure is not limited to any specific type of implementation, and implementation details may vary between different devices, for example.

The interleaver 1404 may be coupled to the polar encoder 1402 in some embodiments, for interleaving a subset of the encoded bits that includes fewer than all of the encoded bits, to obtain partially interleaved encoded bits.

The rate matching module 1406 is shown as an example of a component or device that may provide or support reducing the number of interleaved encoded bits that are output, for transmission for example. Encoded bit reduction may be provided or supported in a different manner than shown.

In an embodiment, an apparatus includes the polar encoder 1402 for encoding input bits by a polar code to obtain a number of encoded bits. The polar code comprises a number of bit indices for placing bit values before encoding, and the bit indices include a first set of bit indices for placing values of the input bits and a second set of bit indices for placing a predetermined bit value. An interface is coupled to the polar encoder 1402, for outputting a first reduced number of the encoded bits starting from a first starting position, and outputting a second reduced number of the encoded bits. The second reduced number of the encoded bits include one or more of the encoded bits not included in the first reduced number of the encoded bits and start from a second starting position different from the first starting position.

More generally, an apparatus or a component thereof such as an encoder 1402 or a processor may be configured to encode (or for encoding) input bits, or programming may include instructions to encode (or for encoding) input bits or to cause a processor to encode input bits, to obtain encoded bits. An apparatus or a component thereof such as an interface coupled to the encoder may be configured to output (or for outputting), or programming may include instructions to output (or for outputting) or to cause a processor to output, encoded bits, such as a first reduced number of encoded bits and a second reduced number of encoded bits.

Embodiments related to such apparatus or non-transitory computer readable storage media may include any one or more of the following features, for example, which are also discussed elsewhere herein:
the apparatus or a component thereof such as the interface may be configured or further configured to transmit (or for transmitting), or programming may include instructions to transmit (or for transmitting) or to cause a processor to transmit: the first reduced number of the encoded bits from a first communication device to a second communication device in a wireless communication network;
the apparatus or a component thereof such as the interface may be configured or further configured to transmit (or for transmitting), or programming may include instructions to transmit (or for transmitting) or to cause a processor to transmit: in an incremental transmission from the first communication device to the second communication device, the second reduced number of the encoded bits;
the apparatus or a component thereof such as an interleaver 1404 coupled to the encoder may be configured or further configured to interleave (or for interleaving), or programming may include instructions to interleave (or for interleaving) or to cause a processor to interleave: a subset of the encoded bits that includes fewer than all of the encoded bits, to obtain partially interleaved encoded bits;
the first reduced number of the encoded bits includes the first reduced number of the partially interleaved encoded bits;
the second reduced number of the encoded bits includes the second reduced number of the partially interleaved encoded bits;
the subset of the encoded bits includes a power of 2 number of the encoded bits;
the first reduced number of the encoded bits includes encoded bits starting from the first starting position and ending at a first ending position, and the second starting position immediately follows the first ending position;
the first reduced number of the encoded bits includes a power of 2 number of the encoded bits starting from the first starting position and ending at the first ending position;
the second reduced number of the encoded bits includes a power of 2 number of the encoded bits starting from the second starting position and ending at a second ending position;
the first reduced number of the encoded bits includes encoded bits starting from the first starting position and ending at a first ending position, the second starting position immediately follows the first ending position and the second reduced number of the encoded bits includes encoded bits starting from the second starting position and ending at a second ending position, and the first reduced number of the encoded bits includes one or more repeated first encoded bits and/or the second reduced number of the encoded bits comprises one or more second repeated encoded bits;
the first ending position is an ending position of a first one of a plurality of power of 2 length blocks of the encoded bits;
the first reduced number of the encoded bits includes the one or more repeated first encoded bits where there are fewer than the first reduced number of the encoded bits between the first starting position and the first ending position;
the second ending position is an ending position of a second one of the plurality of power of 2 length blocks of the encoded bits;
the second reduced number of the encoded bits includes the one or more repeated second encoded bits where there are fewer than the second reduced number of the encoded bits between the second starting position and the second ending position;
the one or more repeated first encoded bits includes one or more of the encoded bits starting from a first repetition starting position and ending at the first ending position;
the first repetition starting position is based on the first reduced number of the encoded bits and the first ending position;
the one or more repeated second encoded bits includes one or more of the encoded bits starting from a second repetition starting position and ending at the second ending position;
the second repetition starting position is based on the second reduced number of the encoded bits and the second ending position;
the apparatus or a component thereof such as a selector, illustrated by way of example as an output selector 1408 coupled to the encoder, may be configured or further configured to select (or for selecting), or programming may include instructions to select (or for selecting) or to cause a processor to select: between outputting the first reduced number of the encoded bits starting from the first starting position and ending at a first ending position with or without one or more repeated first encoded bits;
the apparatus or a component thereof such as a selector, illustrated by way of example as an output selector 1408 coupled to the encoder, may be configured or further configured to select (or for selecting), or programming may include instructions to select (or for selecting) or to cause a processor to select: between outputting the second reduced number of the encoded bits starting from the second starting position immediately following the first ending position and ending at a second ending position with or without one or more repeated second encoded bits;
the apparatus or a component thereof such as a selector, illustrated by way of example as an output selector 1408 coupled to the encoder, may be configured or further configured to select (or for selecting), or programming may include instructions to select (or for selecting) or to cause a processor to select: based on any one or more of: preceding code rate of a preceding reduced number the encoded bits; subsequent code rate of a subsequent reduced number the encoded bits; a redundancy version associated with the outputting; and position of a block of a plurality of blocks of the encoded bits.

For a decoder-side or receiver-side apparatus or a computer program product comprising a non-transitory computer readable storage medium to support decoder-side or receiver-side operations, the apparatus or a component thereof such as an interface may be configured to receive (or for receiving), or programming may include instructions to receive (or for receiving) or to cause a processor to receive, a first reduced number and a second reduced number of encoded bits encoded by a polar code. Such an apparatus or a component thereof such as a decoder may be configured to decode (or for decoding), or programming may include instructions to decode (or for decoding) or to cause a processor to decode, the first reduced number of encoded bits and the second reduced number of encoded bits to obtain decoded input bits. As in other embodiments, the polar code comprises bit indices for placing bit values before encoding, and the bit indices comprise: a first set of bit indices for values of input bits and a second set of bit indices for a predetermined bit value. The second reduced number of the encoded bits include one or more of the encoded bits not included in the first reduced number of the encoded bits and start from a second starting position different from a first starting position of the first reduced number of the encoded bits.

Embodiments related to such apparatus or non-transitory computer readable storage media may include any one or more of the following features, for example, which are also discussed elsewhere herein:
the apparatus or a component thereof such as an interface may be configured or further configured to receive (or for receiving), or programming may include instructions to receive (or for receiving) or to cause a processor to receive, the first reduced number of the encoded bits from a first communication device by a second communication device in a wireless communication network;
the apparatus or a component thereof such as an interface may be configured or further configured to receive (or for receiving), or programming may include instructions to receive (or for receiving) or to cause a processor to receive, in an incremental transmission from the first communication device by the second communication device, the second reduced number of the encoded bits;
a subset of the encoded bits that includes fewer than all of the encoded bits may have been interleaved to obtain partially interleaved encoded bits;
the first reduced number of the encoded bits include the first reduced number of the partially interleaved encoded bits;
the second reduced number of the encoded bits include the second reduced number of the partially interleaved encoded bits;
the subset of the encoded bits includes a power of 2 number of the encoded bits;
the first reduced number of the encoded bits include encoded bits starting from the first starting position and ending at a first ending position, and the second starting position immediately follows the first ending position;
the first reduced number of the encoded bits include a power of 2 number of the encoded bits starting from the first starting position and ending at the first ending position;
the second reduced number of the encoded bits include a power of 2 number of the encoded bits starting from the second starting position and ending at a second ending position;
the first reduced number of the encoded bits include encoded bits starting from the first starting position and ending at a first ending position, the second starting position immediately follows the first ending position and the second reduced number of the encoded bits include encoded bits starting from the second starting position and ending at a second ending position, and the first reduced number of the encoded bits include one or more repeated first encoded bits and/or the second reduced number of the encoded bits comprises one or more second repeated encoded bits;
the first ending position is an ending position of a first one of a plurality of power of 2 length blocks of the encoded bits;
the first reduced number of the encoded bits include the one or more repeated first encoded bits where there are fewer than the first reduced number of the encoded bits between the first starting position and the first ending position;
the second ending position is an ending position of a second one of the plurality of power of 2 length blocks of the encoded bits;
the second reduced number of the encoded bits include the one or more repeated second encoded bits where there are fewer than the second reduced number of the encoded bits between the second starting position and the second ending position;
the one or more repeated first encoded bits include one or more of the encoded bits starting from a first repetition starting position and ending at the first ending position;
the first repetition starting position is based on the first reduced number of the encoded bits and the first ending position;
the one or more repeated second encoded bits include one or more of the encoded bits starting from a second repetition starting position and ending at the second ending position;
the second repetition starting position is based on the second reduced number of the encoded bits and the second ending position;
first reduced number of the encoded bits may have been selected for transmission starting from the first starting position and ending at a first ending position with or without one or more repeated first encoded bits;
the second reduced number of the encoded bits may have been selected for transmission starting from the second starting position immediately following the first ending position and ending at a second ending position with or without one or more repeated second encoded bits;
the selection for transmission with or without the one or more repeated first or second encoded bits may have been based on any one or more of: preceding code rate of a preceding reduced number the encoded bits; subsequent code rate of a subsequent reduced number the encoded bits; a redundancy version associated with the outputting; and position of a block of a plurality of blocks of the encoded bits.

Apparatus embodiments are not in any way restricted to single devices. A system, for example, may include a first communication device and a second communication device. The first communication device may be configured to transmit (or for transmitting) a first reduced number of encoded bits starting from a first starting position and a second reduced number of the encoded bits starting from a second starting position different from the first starting position. The encoded bits are obtained by encoding input bits by a polar code. The second communication device may be configured to receive (or for receiving) t the first reduced number and the second reduced number of the encoded bits, and to decode the first reduced number of encoded bits and the second reduced number of encoded bits to obtain decoded input bits. The polar code comprises a number of bit indices for placing bit values before encoding, and the bit indices comprise: a first set of bit indices for placing values of the input bits and a second set of bit indices for placing a predetermined bit value. The second reduced number of the encoded bits include one or more of the encoded bits not included in the first reduced number of the encoded bits.

The first communication device in a system may also or instead implement, provide, or support other encode-side or transmit-side features disclosed herein, and similarly the second communication device in a system may also or instead implement, provide, or support other decode-side or receive-side features disclosed herein.

More generally, other features disclosed herein may also or instead be provided in method, apparatus, and/or system embodiments.

Embodiments disclosed herein encompass various aspects of polar coding, including encoding and decoding.

Disclosed embodiments may provide a fundamental upgrade of polar codes, and may make polar codes applicable for a much wider set of scenarios.

For example, disclosed embodiments may be implemented as part of a channel coding scheme, and may thus be applicable wherever channel coding is used. This covers a very wide range of scenarios. The flexibility provided by embodiments disclosed herein may help make the associated channel coding scheme particularly suitable for wireless communications.

Possible product deployments, in or in conjunction with which embodiments may be implemented, include network devices such as base stations, access devices such as UEs, robots, sensors, cars, drones, and satellites. Service deployment examples include enhanced mobile broadband (eMBB), ultra-reliable low latency communications (URLLC), massive machine type communications (mMTC)/Internet of things (IoT), and vehicular and industry scenarios. Network deployment examples include 5G+, 6G, WiFi, non-terrestrial networks (NTNs), optical networks, distributed networks, and self-organized networks. These are illustrative and non-limiting examples, and other deployments, implementations, or applications are possible.

Potential advantageous effects of disclosed embodiments include benefits of rateless polar codes, and additionally addressing IR-HARQ challenges.

This may entail providing flexibility, simplicity and coding gain, in that arbitrary length with 1-bit fine granularity of each RV can be provided by IR-HARQ based on rateless polar codes as disclosed herein. Such flexibility is new to polar codes. The overall coding gain associated with combining multiple RVs is comparable to that of a separately constructed long code for a single transmission.

Some embodiments herein also provide simple descriptions that may be desirable for communication standards or specifications, or in other words may be more standard-friendly. For example, a set of key parameters, including the cyclic buffer design, starting points of RVs, and a maximum number of matrix extensions, etc., may be specified in a very concise manner. An encoding chain can also be easily described in future standards or specifications.

To summarize, IR-HARQ based on rateless polar codes as disclosed herein may be advantageous in providing one or more of flexibility, simplicity, and coding gain. IR-HARQ protocols for polar codes may be advantageous in providing for more standard-friendly description or specification. Decoding as disclosed herein may be beneficial in helping avoid catastrophic performance degradation that may otherwise affect conventional approaches that use or support only sequential decoding.

The coding gain performance of polar IR-HARQ as disclosed herein may be compared with both polar CC-HARQ and a separately constructed long code of the same length as the sum lengths of transmitted RVs.

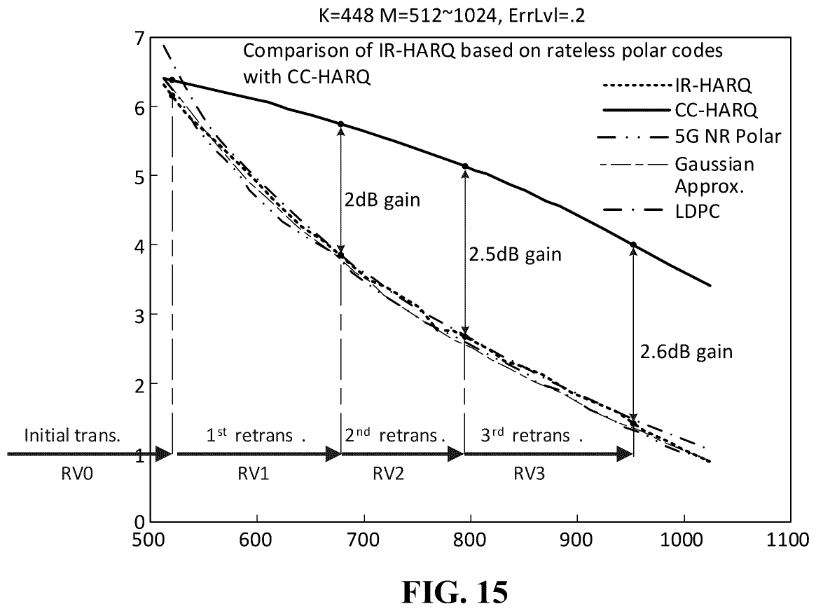

As an example, FIG. 15 includes plots illustrating error correction performance, for N₀=512 and M₁=1024. The x-axis is the sum or cumulative code length of multiple transmissions, and the y-axis is the required signal to noise ratio (SNR) to achieve block error rate (BLER)=10-2. All four RVs are transmitted, including an initial transmission and 3 retransmissions, denoted by RV0, RV1, RV2, RV3, respectively. As shown, the coding gain after the 1^{st} retransmission (at total length 680) for “IR-HARQ” consistent with the present disclosure is 2 dB over CC-HARQ, the coding gain after the 2^{nd} retransmission (at total length 800) is 2.5 dB over CC-HARQ, and the coding gain after the 3rd retransmission (at total length 950) is 2.6 dB over CC-HARQ. At the same time, the performance of IR-HARQ after the 1^{st}, 2^{nd}, 3^{rd} retransmissions is almost the same as separately constructed long codes of length (RV0+RV1)=680, length (RV0+RV1+RV2)=800 and length (RV0+RV1+RV2+RV3)=950, respectively, for 5G NR Polar and Gaussian approximation. LDPC performance is also shown for comparison.

The plots in FIG. 15 are for an example of K=448 and M=512 to 1024 for a range of code lengths and code rates. Similar or different performance may be observed under similar or different conditions.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

Although aspects of the present invention have been described with reference to specific features and embodiments thereof, various modifications and combinations can be made thereto without departing from the invention. The description and drawings are, accordingly, to be regarded simply as an illustration of some embodiments of the invention as defined by the appended claims, and are contemplated to cover any and all modifications, variations, combinations or equivalents that fall within the scope of the present invention. Therefore, although embodiments and potential advantages have been described in detail, various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

1. A method comprising:
encoding input bits by a polar code to obtain a number of encoded bits, the polar code comprising a plurality of bit indices for placing bit values before encoding, the plurality of bit indices comprising: a first set of bit indices for placing values of the input bits and a second set of bit indices for placing a predetermined bit value;
outputting a first reduced number of encoded bits starting from a first starting position; and
outputting a second reduced number of encoded bits, the second reduced number of encoded bits comprising one or more of the encoded bits not included in the first reduced number of encoded bits and starting from a second starting position different from the first starting position.

2. The method of claim 1, further comprising:
transmitting the first reduced number of encoded bits from a first communication device to a second communication device in a wireless communication network; and
transmitting, in an incremental transmission from the first communication device to the second communication device, the second reduced number of encoded bits.

3. The method of claim 1, further comprising:
interleaving a subset of the encoded bits that includes fewer than all of the encoded bits, to obtain partially interleaved encoded bits,
the first reduced number of the encoded bits comprising a first reduced number of the partially interleaved encoded bits; and
the second reduced number of the encoded bits comprising a second reduced number of the partially interleaved encoded bits.

4. The method of claim 3, wherein the subset of encoded bits comprises a power-of-2 number of encoded bits.

5. The method of claim 1,
wherein the first reduced number of encoded bits comprises encoded bits starting from the first starting position and ending at a first ending position, and
wherein the second starting position is adjacent to and follows the first ending position.

6. A method comprising:
receiving a first reduced number of encoded bits and a second reduced number of encoded bits encoded by a polar code,
the second reduced number of encoded bits comprising one or more of the encoded bits not included in the first reduced number of encoded bits and starting from a second starting position different from a first starting position of the first reduced number of the encoded bits,
the polar code comprising a plurality of bit indices for placing bit values before encoding, the plurality of bit indices comprising: a first set of bit indices for placing values of input bits and a second set of bit indices for placing a predetermined bit value; and
decoding the first reduced number of encoded bits and the second reduced number of encoded bits to obtain decoded input bits.

7. The method of claim 6, wherein the receiving comprises:
receiving the first reduced number of encoded bits from a first communication device by a second communication device in a wireless communication network; and
receiving, in an incremental transmission from the first communication device by the second communication device, the second reduced number of encoded bits.

8. The method of claim 6, wherein:
a subset of the encoded bits that includes fewer than all of the encoded bits are interleaved to obtain partially interleaved encoded bits,
the first reduced number of the encoded bits comprises a first reduced number of the partially interleaved encoded bits, and
the second reduced number of the encoded bits comprises a second reduced number of the partially interleaved encoded bits.

9. The method of claim 8, wherein the subset of encoded bits comprises a power-of-2 number of encoded bits.

10. The method of claim 6,
wherein the first reduced number of encoded bits comprises encoded bits starting from the first starting position and ending at a first ending position, and
wherein the second starting position is adjacent to and follows the first ending position.

11. An apparatus comprising:
an encoder configured to encode input bits by a polar code to obtain a number of encoded bits, the polar code comprising a plurality of bit indices for placing bit values before encoding, the bit indices comprising: a first set of bit indices for placing values of the input bits and a second set of bit indices for placing a predetermined bit value; and
an interface coupled to the encoder, configured to:
output a first reduced number of encoded bits starting from a first starting position; and
output a second reduced number of encoded bits, the second reduced number of encoded bits comprising one or more of the encoded bits not included in the first reduced number of encoded bits and starting from a second starting position different from the first starting position.

12. The apparatus of claim 11, the interface being further configured to:
transmit the first reduced number of encoded bits from a first communication device to a second communication device in a wireless communication network; and
transmit, in an incremental transmission from the first communication device to the second communication device, the second reduced number of encoded bits.

13. The apparatus of claim 11, further comprising:
an interleaver, coupled to the encoder, configured to interleave a subset of the encoded bits that includes fewer than all of the encoded bits, to obtain partially interleaved encoded bits,
the first reduced number of the encoded bits comprising a first reduced number of the partially interleaved encoded bits; and
the second reduced number of the encoded bits comprising a second reduced number of the partially interleaved encoded bits.

14. The apparatus of claim 13, wherein the subset of encoded bits comprises a power-of-2 number of encoded bits.

15. The apparatus of claim 11,
wherein the first reduced number of encoded bits comprises encoded bits starting from the first starting position and ending at a first ending position, and
wherein the second starting position is adjacent to and follows the first ending position.

16. An apparatus comprising:
an interface configured to receive a first reduced number of encoded bits and a second reduced number of encoded bits encoded by a polar code,
the second reduced number of encoded bits comprising one or more of the encoded bits not included in the first reduced number of encoded bits and starting from a second starting position different from a first starting position of the first reduced number of the encoded bits,
the polar code comprising a plurality of bit indices for placing bit values before encoding, the plurality of bit indices comprising: a first set of bit indices for placing values of input bits and a second set of bit indices for placing a predetermined bit value; and
the apparatus further comprising:
a decoder, coupled to the interface, configured to decode the first reduced number of encoded bits and the second reduced number of encoded bits to obtain decoded input bits.

17. The apparatus of claim 16, wherein the interface is configured to:
receive the first reduced number of encoded bits from a first communication device by a second communication device in a wireless communication network; and
receive, in an incremental transmission from the first communication device by the second communication device, the second reduced number of encoded bits.

18. The apparatus of claim 16, wherein:
a subset of the encoded bits that includes fewer than all of the encoded bits are interleaved to obtain partially interleaved encoded bits,
the first reduced number of the encoded bits comprises a first reduced number of the partially interleaved encoded bits, and
the second reduced number of the encoded bits comprises a second reduced number of the partially interleaved encoded bits.

19. The apparatus of claim 18, wherein the subset of encoded bits comprises a power-of-2 number of encoded bits.

20. The apparatus of claim 16,
wherein the first reduced number of encoded bits comprises encoded bits starting from the first starting position and ending at a first ending position, and
wherein the second starting position is adjacent to and follows the first ending position.
